(19) United States
(12) Patent Application Publication
(10) Pub. No.: US 2025/0105594 A1
(43) Pub. Date: Mar. 27, 2025

(54) SELF-MIXING INTERFEROMETRY USING BACKSIDE-EMITTING VCSEL DIODE WITH INTEGRATED PHOTODETECTOR

(71) Applicant: Apple Inc., Cupertino, CA (US)

(72) Inventors: Pengfei Qiao, El Cerrito, CA (US); Fei Tan, Sunnyvale, CA (US); Tong Chen, Fremont, CA (US); Qinghong Du, Fremont, CA (US); Siddharth Joshi, Saint-Egreve (FR); Nicolas Hotellier, Champagnier (FR); Alexander Hein, Munich (DE); Pierre-Antoine Delean, Domene (FR)

(21) Appl. No.: 18/892,108

(22) Filed: Sep. 20, 2024

Related U.S. Application Data
(60) Provisional application No. 63/540,253, filed on Sep. 25, 2023.

(51) Int. Cl. H01S 5/183; H01S 5/026; H01S 5/042; H01S 5/30

(52) U.S. Cl. CPC H01S 5/18394; H01S 5/0262; H01S 5/0421; H01S 5/18344; H01S 5/18388; H01S 5/3095

(57) ABSTRACT

Embodiments described herein include an optoelectronic sensing device having a vertical cavity surface emitting laser (VCSEL), a resonance cavity photodetector (RCPD), and a tunnel junction. The VCSEL is at least partly defined by a first set of semiconductor layers disposed on a substrate. The first set of semiconductor layers includes a first active region. The VCSEL is configured to emit laser light towards the substrate, upon application of a first bias voltage, and undergo self-mixing interference upon reception of reflections or backscatters thereof. The RCPD is vertically adjacent to the VCSEL and is at least partly defined by a second set of semiconductor layers disposed on the substrate. The second set of semiconductor layers includes a second active region. The RCPD is configured to detect, upon application of a second bias voltage, the self-mixing interference. The tunnel junction is disposed between the first active region and the second active region.

### CROSS-REFERENCE TO RELATED APPLICATION

This application is a non-provisional application which claims the benefit under 35 U.S.C. § 119 (e) of U.S. Provisional Patent Application No. 63/540,253, filed Sep. 25, 2023, the contents of which are incorporated herein by reference as if fully disclosed herein.

### FIELD

The described embodiments generally relate to optical sensing and, more particularly, to optical sensing based on self-mixing interferometry (SMI).

### BACKGROUND

Electronic devices can be equipped with optoelectronic sensors. For example, optoelectronic sensors may be included in portable electronic devices such as mobile phones, tablet computers, laptop computers, cameras, portable music players, portable terminals, vehicle navigation systems, robot navigation systems, electronic watches, health or fitness tracking devices, and other portable or mobile devices. Optoelectronic sensors may also be included in devices that are semi-permanently located (or installed) at a single location (e.g., security cameras, doorbells, door locks, thermostats, refrigerators, or other appliances). Some of these electronic devices may include one or more input elements or surfaces, such as cameras, buttons, or touch screens, through which a user may enter commands or data via a touch, press, gesture, or image. The touch, press, gesture, or image may be detected by components of the electronic device (e.g., one or more optoelectronic sensors) that detect presence, distance, location, motion, topology, or other parameters. The same and/or other electronic devices may also or alternatively include one or more sensors, which sensors may sense proximity, distance, particle speed, or other parameters without receiving an intentional user input.

Some optoelectronic sensors may include a light source (e.g., a laser) that emits a beam of light, toward or through an input surface. Distance, location, motion, topology, or other parameters of the input surface, or of an object on an opposite side of the input surface, may be inferred from reflections or backscatter of the emitted light from the input surface and/or the object.

Some optoelectronic sensors may include a vertical-cavity surface-emitting laser (VCSEL) diode. A VCSEL diode may undergo self-mixing interference, in which reflections of its emitted laser light are received back into its resonance cavity. The self-mixing interference may induce a shift in a property of the laser light generated within the resonance cavity, such as wavelength, to a different state from what it would be in the absence of received reflections (“free emission”). In the case that the received reflections are from an input surface or object, the shift in the property may be correlated, for example, with the displacement, distance, motion, speed, or velocity of the input surface or object that caused the reflections.

### SUMMARY

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

Embodiments of this disclosure are directed to an optoelectronic sensing device having a vertical cavity surface emitting laser (VCSEL), a resonance cavity photodetector (RCPD), and a tunnel junction. The VCSEL is at least partly defined by a first set of semiconductor layers disposed on a substrate. The first set of semiconductor layers includes a first active region. The VCSEL is configured to emit laser light towards the substrate, upon application of a first bias voltage, and undergo self-mixing interference upon reception of reflections or backscatters of the emitted laser light from a target object. The RCPD is vertically adjacent to the VCSEL and is at least partly defined by a second set of semiconductor layers disposed on the substrate. The second set of semiconductor layers includes a second active region. The RCPD is configured to detect, upon application of a second bias voltage, the self-mixing interference during emission of the laser light by the VCSEL. The tunnel junction is disposed between the first active region and the second active region.

Embodiments of this disclosure are further directed to an optoelectronic sensing device having a substrate, a set of stacked semiconductor layers, and a grating structure disposed on the set of stacked semiconductor layers. The substrate has a front side and a back side. The set of stacked semiconductor layers is disposed on the front side and defines a vertical cavity surface emitting laser (VCSEL) and a resonance cavity photodetector (RCPD). The VCSEL has a first active region within a resonance cavity thereof. The VCSEL is configured to emit, upon application of a first bias voltage, a primary emission towards the substrate and through the back side. The RCPD has a second active region offset from the first active region.

Embodiments of this disclosure are also directed to an optoelectronic sensing device having a substrate, a set of stacked semiconductor layers, and at least one electrical conductor. The substrate has a front side and a back side. The set of stacked semiconductor layers is disposed on the front side and define a set of mesas. The set of mesas includes a first set of one or more mesas and a second set of one or more mesas. Each mesa in the first set of one or more mesas includes a vertical cavity surface emitting laser (VCSEL) and a resonance cavity photodetector (RCPD). The VCSEL has a first active region within a resonance cavity thereof. The VCSEL is configured to emit, upon application of a first bias voltage, a primary emission towards the substrate and through the back side. The RCPD has a second active region offset from the first active region. The RCPD is configured to detect, upon application of a second bias voltage, a self-mixing interference of the primary emission in a laser cavity of the VCSEL upon reception of reflections or backscatters thereof. The at least one electrical conductor is electrically connected to an element of a first mesa in the first set of one or more mesas and routed over a portion of a second mesa in the second set of one or more mesas.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 shows a cross-sectional view of a first example structure of a backside-emitting vertical cavity surface emitting laser (VCSEL) diode integrated with a resonance cavity photodetector (RCPD), where the RCPD is disposed away from a primary emission of the VCSEL diode, according to certain aspects of the present disclosure;

FIG. 2 shows a cross-sectional view of a second example structure of a backside-emitting vertical cavity surface emitting laser (VCSEL) diode integrated with a resonance cavity photodetector (RCPD), where the RCPD is disposed along a primary emission of the VCSEL diode, according to certain aspects of the present disclosure;

FIG. 3 shows a cross-sectional view of an example optoelectronic sensing device, having the first example structure of a backside-emitting VCSEL diode integrated with an RCPD shown in FIG. 1, according to certain aspects of the present disclosure;

FIG. 4 shows a cross-sectional view of a grating structure configured to be disposed on a set of stacked semiconductor layers on a substrate forming an example optoelectronic sensing device, according to certain aspects of the present disclosure;

FIGS. 5A-5D show schematic representations of an operational circuit in the example optoelectronic sensing device of FIG. 3 depending on whether the backside-emitting VCSEL diode has a cathode load or an anode drive, according to certain aspects of the present disclosure;

FIG. 6 shows a schematic representation of an operational circuit in the example optoelectronic sensing device of FIG. 3, where a bias polarity of the RCPD is switched in the time domain, according to certain aspects of the present disclosure;

FIG. 7 shows a cross-sectional view of an example optoelectronic sensing device, having the second example structure of a backside-emitting VCSEL diode integrated with an RCPD shown in FIG. 2, according to certain aspects of the present disclosure;

FIGS. 8A-8D show schematic representations of an operational circuit in the example optoelectronic sensing device of FIG. 7 depending on whether the backside-emitting VCSEL diode has an anode drive or a cathode load, according to certain aspects of the present disclosure;

FIGS. 9A-9B show a cross-sectional view and a corresponding schematic representation of an operational circuit respectively, of a first example optoelectronic sensing device having an extended resonance cavity in an emission side of a backside-emitting VCSEL diode having multi-junction structures in an optoelectronic sensing device, according to certain aspects of the present disclosure;

FIGS. 10A-10B show a cross-sectional view and a corresponding schematic representation of an operational circuit respectively, of a first example optoelectronic sensing device having multiple sets of a backside-emitting VCSEL diode integrated with an RCPD with a first arrangement of electrical connections between the multiple sets, according to certain aspects of the present disclosure;

FIGS. 11A-11B show a cross-sectional view and a corresponding schematic representation of an operational circuit respectively, of a second example optoelectronic sensing device having multiple sets of a backside-emitting VCSEL diode integrated with an RCPD with a second arrangement of electrical connections between the multiple sets, according to certain aspects of the present disclosure;

FIGS. 12A-12B show a cross-sectional view and a corresponding schematic representation of an operational circuit respectively, of a second example optoelectronic sensing device having an extended resonance cavity in an emission side of a backside-emitting VCSEL diode having multi-junction structures in an optoelectronic sensing device, according to certain aspects of the present disclosure;

FIGS. 13A-13B show a perspective view and corresponding cross-sectional view respectively, of a first example set of the optoelectronic sensing devices, such as a set of the optoelectronic sensing devices shown and described with reference to FIGS. 9A-9B or 12A-12B;

FIG. 14 shows a top view of an example array of the optoelectronic sensing devices shown and described with reference to FIGS. 13A-13B;

FIGS. 15A-15B show a perspective view and corresponding cross-sectional view respectively, of a second example set of the optoelectronic sensing devices, such as a set of the optoelectronic sensing devices shown and described with reference to FIGS. 9A-9B or 12A-12B;

FIG. 16 shows a top view of an example array of the optoelectronic sensing devices shown and described with reference to FIGS. 15A-15B;

FIG. 17 shows a top view of a first example layout of an optoelectronic sensing device, such as an optoelectronic sensing device shown and described with reference to FIGS. 9A-9B or 12A-12B;

FIG. 18 shows a top view of a second example layout of an optoelectronic sensing device, such as an optoelectronic sensing device shown and described with reference to FIGS. 9A-9B or 12A-12B;

FIG. 19 shows a top view of a first array of the second example layout of an optoelectronic sensing device shown and described with reference to FIG. 18;

FIG. 20 shows a top view of a second array of the second example layout of an optoelectronic sensing device shown and described with reference to FIG. 18; and

FIG. 21 shows an example electrical block diagram of an electronic device having the optoelectronic sensor, according to certain aspects of the present disclosure.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

The present disclosure is susceptible to various modifications and alternative forms, and some representative embodiments have been shown by way of example in the drawings and will be described in detail herein. It should be understood, however, that the invention is not intended to be limited to the particular forms disclosed. Rather, the disclosure is to cover all modifications, equivalents, and alternatives falling within the spirit and scope of the invention as defined by the appended claims.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Various embodiments are described with reference to the attached figures, where like reference numerals are used throughout the figures to designate similar or equivalent elements. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively.

Additionally, directional terminology, such as “top”, “bottom”, “upper”, “lower”, “front”, “back”, “over”, “under”, “above”, “below”, “left”, “right”, etc. is used with reference to the orientation of some of the components in some of the figures described below. Because components in various embodiments can be positioned in a number of different orientations, directional terminology is used for purposes of illustration only and is in no way limiting. The directional terminology is intended to be construed broadly, and therefore should not be interpreted to preclude components being oriented in different ways. These words are intended to relate to the equivalent direction as depicted in a reference illustration; as understood contextually from the object(s) or element(s) being referenced, such as from a commonly used position for the object(s) or element(s); or as otherwise described herein. Further, it is noted that the term “signal” means a waveform (e.g., electrical, optical, magnetic, mechanical, or electromagnetic) capable of traveling through a medium such as DC, AC, sinusoidal-wave, triangular-wave, square-wave, vibration, and the like.

Also, as used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of any of the items, and/or at a minimum one of any combination of the items, and/or at a minimum one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

The embodiments described herein are directed to optoelectronic sensing devices, such as those that may be used for touch or input sensors, proximity or particle sensors, or other types of sensors, and to their structures. Such optoelectronic sensing devices may use one or more backside-emitting vertical cavity surface emitting laser (VCSEL) diodes with integrated photodiodes, such as resonance cavity photodiodes (RCPDs), that receive emitted laser light from the VCSEL diode. An electronic device may use such an optoelectronic sensing device as part of a system for detecting a displacement, distance, motion, speed, or velocity of an object (or “target”). Such an object may be a component of the electronic device, such as an input surface or touchpad, or the target may be external to the electronic device; for example, the optoelectronic sensing device may be part of an autofocus system of a camera and used to detect a distance to, or motion of, an external object. Hereinafter, for convenience, all such possible measured kinematic parameters of the target will be referred to simply as “distance or motion.”

In a backside-emitting VCSEL diode, in general, laser light is emitted from a resonance cavity containing at least one active region (a p-n junction surrounding its laser cavity) towards and through a substrate on which the backside-emitting VCSEL diode is formed. Reflections of the emitted laser light may be received back into the resonance cavity and induce self-mixing interference in which a property of the laser light, such as wavelength, is altered from the value it would have in the absence of receiving reflections. The alterations in the property can then be correlated with distance or motion of the object causing the reflections.

One way the altered property may be detected is by changes in one or more electrical properties of the backside-emitting VCSEL diode itself, such as voltage, current, power, etc. Alternatively, the altered emitted laser light may be received by a photodiode associated with the backside-emitting VCSEL diode, the photodiode having an output parameter related to the altered property of the self-mixed emitted laser light of the VCSEL diode.

In various embodiments described herein, a backside-emitting VCSEL diode may be structured, when forward-biased, to emit a primary emission from the active region towards an object through an emission side of the optoelectronic sensing device, as well as towards a photodiode integrated therein. The alteration of the property of the laser light due to self-mixing with reflections from the object is then present in the primary emission received by the photodiode that, when reverse-biased, may produce a measurable electrical parameter with a value related to the altered property of the primary emission, from which a distance or motion of the object may be inferred.

In some embodiments described herein, a photodiode is integrally formed on a semiconductor substrate, for example using an epitaxial deposition technique, on which the VCSEL is formed. The photodiode may be disposed between the semiconductor substrate and the VCSEL diode, or the VCSEL diode may be disposed between the semiconductor substrate and the photodiode. Various electrical connections may be formed in or on the substrate, the VCSEL diode, and/or the photodiode to, for example, bias the VCSEL diode, to receive signals from the photodiode, or other electrical signaling. A VCSEL diode may have its input current (or voltage) modulated to provide modulation of the primary emission. Such modulation of the primary emission may allow for inferring the distance and motion of a target.

Additional photodetector structures such as one or more gain stage layers such as, but not limited to, an indium gallium arsenide (InGaAs) layer, an aluminum gallium arsenide (AlGaAs) layer, can be formed in the resonance cavity of the VCSEL diode to improve efficiency of absorption of the primary emission into the laser cavity of the VCSEL diode. Further, tunnel junctions can be inserted between the photodiode junction of the photodiode and the laser junction of the VCSEL diode, depending on the polarities of the junctions, to improve carrier injection and extraction and reduce operating voltage of the optoelectronic sensing device.

In some embodiments, multi-junction structures consisting of multiple active regions (e.g., multiple pairs of a barrier layer alternating with a quantum well layer), and highly-doped tunnel junctions interspersed therebetween can be stacked vertically in the resonance cavity of the VCSEL diode. The multi-junction structures can have one or more oxide layers formed on top, bottom, or in the middle. Such a multi-junction (MJ) VCSEL diode may emit laser light with different properties than would be emitted by a comparable single junction (SJ) VCSEL diode operating at a similar current level. With multi-junction structures, MJ VCSEL diodes operate at increased voltage levels (compared to a similar SJ VCSEL diode operating at a similar current level) and may provide multiple factors of increase of gain of, for example, output power. Also, the center frequency of the emitted laser light may be increased, which may improve signal-to-noise ratio (SNR) due to reduced 1/f noise. Increased SNR and higher operating frequency may also allow for improved spatial resolution of targets by an optoelectronic sensing device making use of MJ VCSEL diodes, due to increased efficiency and tunable range for wavelength modulation of the emitted laser light by the MJ VCSEL diode, which in turn enables better measurement of the electrical parameter related to the self-mixing interference of the emitted laser light. Thus, the multi-junction structures improve performance of the optoelectronic sensing device through faster signaling, wider sampling and reduced complexity.

In some embodiments, an optoelectronic sensing device with multi-junction structures may also have an extended resonance cavity extending from the VCSEL diode to an on-chip lens (OCL) formed on a rear end of the substrate and includes the substrate. The extended resonance cavity significantly reduces laser linewidth and extends the laser coherence length needed for long-range sensing.

In some embodiments, an optoelectronic sensing device may have a semiconductor wafer or chip that is disposed on a front side thereof and define a set of mesas, where at least some mesas include a VCSEL diode with an integrated photodiode. The VCSEL diode is configured to emit, when forward-biased, a primary emission of laser light from an active region surrounding its laser cavity towards the substrate and through the back side. The photodiode may be an RCPD having an active region offset from the active region of the VCSEL diode. The RCPD is configured to detect, when reverse-biased, a self-mixing interference of the primary emission upon reception of reflections or backscatters thereof. Adjacent mesas are connected to a power supply and to each other via one or more electrical conductors.

Although specific optoelectronic sensing devices are shown in the figures and described below, the embodiments described herein may be used with various electronic devices including, but not limited to, mobile phones, personal digital assistants, a time keeping device, a health monitoring device, a wearable electronic device, an input device (e.g., a stylus), a desktop computer, electronic glasses, etc. Although various electronic devices are mentioned, the optoelectronic sensing devices of the present disclosure may also be used in conjunction with other products and combined with various materials.

These and other embodiments are discussed below with reference to FIGS. 1-12. However, those skilled in the art will readily appreciate that the detailed description given herein with respect to these figures is for explanatory purposes only and should not be construed as limiting.

FIG. 1 shows a cross-sectional view of a first example structure 100 of a backside-emitting vertical cavity surface emitting laser (VCSEL) diode 120 integrated with a resonance cavity photodetector (RCPD) 130, where the RCPD 130 is disposed in the path of a secondary emission, away from a primary emission 140, of the VCSEL diode 120. The VCSEL diode 120 is formed on a semiconductor substrate 110, such as by an epitaxial deposition technique. The VCSEL diode 120 includes a first active region 128 having one or more quantum well structures. The first active region 128 forms a highly-doped p-n junction that, when forward-biased, allows charge carriers crossing the p-n junction to induce the primary emission 140 of laser light therefrom and towards the substrate 110. On either side of the first active region 128, distributed Bragg diffraction layers formed as alternating semiconductor layers of high and low refractive indices are present, and may function as the mirrors in the resonance cavity of the VCSEL diode 120.

This primary emission 140, upon reflection and backscattering from a target object 150, is received into a laser cavity of the first active region 128, where it undergoes self-mixing interference. As a result, an electrical property of the VCSEL diode 120 and/or the primary emission 140 is altered.

The RCPD 130 is formed, such as by an epitaxial deposition technique, over the VCSEL diode 120 and includes a second active region 138. The RCPD 130 receives the laser light of the VCSEL diode 120 having the altered electrical property. The second active region 138 is configured, when reverse-biased, to detect the altered electrical property of the self-mixed laser light of the VCSEL diode 120, and produce an output signal dependent on the wavelength of the self-mixed primary emission of the VCSEL diode 120. A distance or motion of the target object 150 that reflects or backscatters the primary emission 140 can be determined based on the output signal from the RCPD 130.

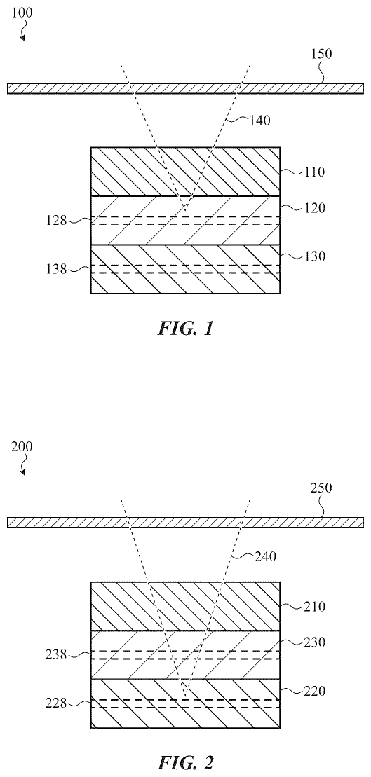

FIG. 2 shows a cross-sectional view of a second example structure 200 of a backside-emitting vertical cavity surface emitting laser (VCSEL) diode 220 integrated with a resonance cavity photodetector (RCPD) 230, where the RCPD 230 is disposed along a primary emission 240 of the VCSEL diode 220.

The RCPD 230 is formed, such as by an epitaxial deposition technique, over a semiconductor substrate 210 and includes a first active region 238. The VCSEL diode 220 is formed on the RCPD 230, also by an epitaxial deposition technique. The VCSEL diode 220 includes a second active region 228 having one or more quantum well structures. The second active region 228 forms a highly-doped p-n junction that, when forward-biased, allows charge carriers crossing the p-n junction to induce the primary emission 240 of laser light therefrom and towards the substrate 210. On either side of the second active region 228, distributed Bragg diffraction layers formed as alternating semiconductor layers of high and low refractive indices are present, and may function as the mirrors in the resonance cavity of the VCSEL diode 220.

This primary emission 240, upon reflection and backscattering from a target object 250, is received into a laser cavity of the second active region 228, where it undergoes self-mixing interference. As a result, an electrical property of the VCSEL diode 220 and/or the primary emission 240 is altered.

The RCPD 230 also receives the laser light of the VCSEL diode 220 having the altered electrical property. The first active region 238 is configured, when reverse-biased, to detect the altered electrical property of the self-mixed laser light of the VCSEL diode 220, and produce an output signal dependent on the wavelength of the self-mixed primary emission 240 of the VCSEL diode 220. A distance or motion of the target object 250 receiving the primary emission 240 can be determined based on the output signal from the RCPD 230.

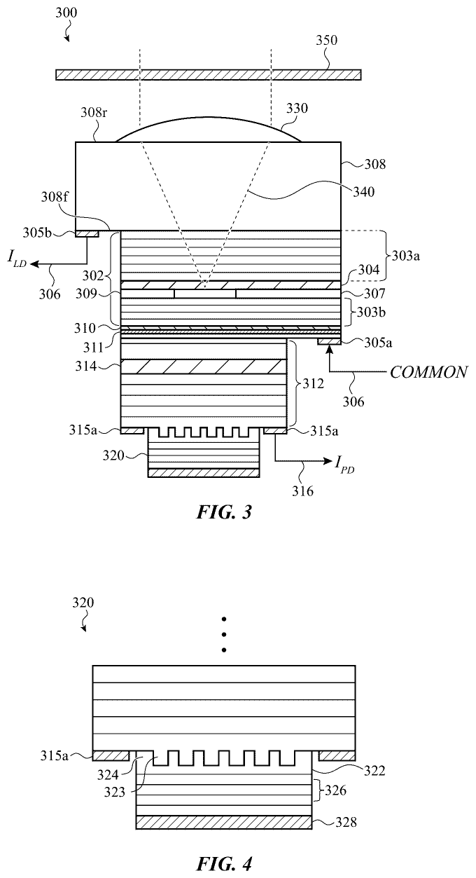

FIG. 3 shows a cross-sectional view of an example optoelectronic sensing device 300, having the first example structure 100 of a backside-emitting VCSEL diode integrated with an RCPD (shown in FIG. 1). In particular, a backside-emitting VCSEL diode 302 is integrated with an RCPD 312 that is disposed in the path of a secondary emission, away from a primary emission 340 generated from the VCSEL diode 302 under forward bias. The RCPD 312 receives an altered primary emission from the VCSEL diode 302 after the primary emission 340 undergoes self-mixing interference upon reception of reflections or backscatters therein.

The optoelectronic sensing device 300 is made by first depositing a set of stacked semiconductor layers on a front side 308f of a substrate 308 to form the VCSEL diode 302, and then forming the RCPD 312 on the VCSEL diode 302. An on-chip lens 330 is disposed on a rear side 308r of the substrate 308, and is configured to collimate, focus, or expand laser light emitted by the VCSEL diode 302 and to collect a returning laser light back into the laser cavity of the first active region 304 in the VCSEL diode 302 for coherent mixing.

The VCSEL diode 302 may include an emission side (or “top side”) distributed Bragg reflector (hereinafter “DBR”) layer 303a that functions as a first (or “emission side”) mirror of a laser structure. The emission side DBR layer 303a may include a set of pairs of alternating materials having different refractive indices. Each such pair of alternating materials will be termed herein a Bragg pair. One or more of the materials in the emission side DBR layer 303a may be doped to be p-type and so form a part of the anode section of a p-n diode junction of the VCSEL diode 302. An exemplary pair of materials that may be used to form the emission side DBR layer 303a are aluminum gallium arsenide (AlGaAs) and gallium arsenide (GaAs).

The VCSEL diode 302 may also include a base side DBR layer 303b that functions as a second (or “base side” or “bottom side”) mirror of a laser. The base side DBR layer 303b may also include a set of Bragg pairs of alternating materials having different refractive indices. One or more of the materials in the base side DBR layer 303b may be doped to be n-type and so form a part of the cathode section of a p-n diode structure. An exemplary pair of materials that may be used to form the base side DBR layer 303b are aluminum arsenide (AlAs) and gallium arsenide (GaAs).

In some embodiments, the DBR layers 303a and 303b may be formed by semiconductor epitaxy and either of the semiconductors GaAs, AlxGal-xAs for (0<x≤1), or from other semiconductor materials. In other embodiments, the DBR layers 303a and 303b may be formed from dielectric materials. Examples of such dielectrics include, but are not limited to, amorphous silicon (a-Si), silicon oxide (SiO₂), SiO₂/niobium pentoxide (Nb₂O₅), and SiO₂/tantalum pentoxide (Ta₂O₅). In yet other embodiments, the DBR layers 303a and 303b may be formed as a hybrid of semiconductor materials and dielectric materials.

The VCSEL diode 302 may include an active region 307 that functions in part as the resonance cavity. In laser diodes, such as the VCSEL diode 302, the active region 307 may include one or more quantum wells. In some embodiments such as shown in FIG. 3, the active region 307 of the VCSEL diode 302 may be adjacent to an oxide layer 309 having an aperture through which the primary emission 340 escapes. In some embodiments such as shown in FIG. 3, the active region 307 further includes one or more gain stage layers 304 (e.g., InGaAs layer, AlGaAs layer) formed in the resonance cavity of the VCSEL diode 302 to improve efficiency of absorption of the primary emission 340.

The VCSEL diode 302 may be formed by epitaxial growth of the layers for each of the emission side layer 303a and the base side DBR layer 303b, the active region 307 and the oxide layer 309, and possibly other layers. These various layers may be formed by epitaxial growth on the substrate 308. Electrical supply contacts 305a, 305b may be formed on the emission side layer and base side layers of the VCSEL diode 302.

The RCPD 312 is formed on the VCSEL diode 302. In some embodiments, the RCPD 312 may include an active region 314 (offset from the active region 307 of the VCSEL diode 302) and an electrical supply contact 315a. The active region 314 may include one or more gain layers (e.g., InGaAs layer, AlGaAs layer) to improve efficiency of absorption of the altered primary emission 340 after it undergoes self-mixing interference in the active region 307 of the VCSEL diode 302. The electrical supply contact 315a forms a ring or horseshoe connection on the top side of the RCPD 312. A grating structure 320, as further described with respect to FIG. 4, may be vertically disposed on the set of stacked semiconductor layers forming the RCPD 312.

One or more tunnel junctions 310 and an additional gain layer 311 may be disposed between the active region 307 of the VCSEL diode 302 and the active region 314 of the RCPD 312. Depending on the polarities of the junctions, the tunnel junction 310 may help improve carrier injection/extraction from the VCSEL diode 302 to the RCPD 312 and reduce the operating voltage of the optoelectronic sensing device 300.

As an example, in one embodiment, the tunnel junction 310 of the VCSEL diode 302 may have a turn-on voltage (the forward bias voltage that initiates lasing) of approximately 1.3 V, so the resulting turn-on voltage of the VCSEL diode 302 as a whole would become approximately 2.6 V. The current, however, would remain constant for a single tunnel junction, which in one embodiment would be 0.5 mA.

The tunnel junction 310 of the VCSEL diode 302 may be formed with both a heavily doped n-type layer and a heavily doped p-type layer. Examples of n-type dopants include, but are not limited to, silicon (Si), tellurium (Te), and selenium (Se). Examples of p-type dopants include, but are not limited to, carbon (C), zinc (Zn), and beryllium (Be). A heavily doped concentration value may be a doping concentration of at least 1018/cm³, and for some dopants may be as high as 1020/cm³, although other concentrations are possible.

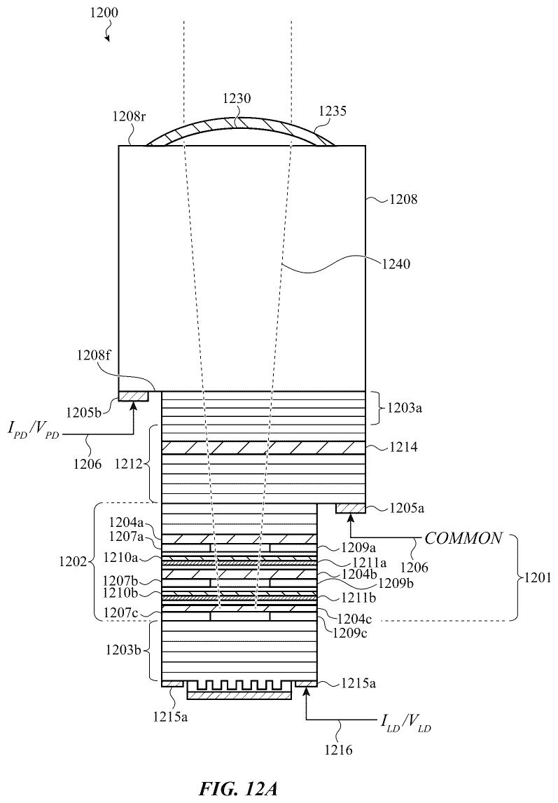

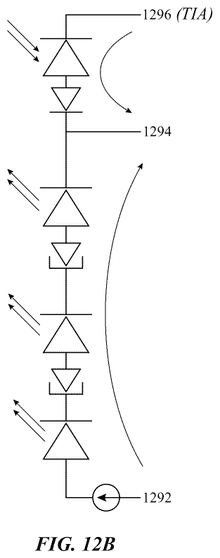

As shown in FIG. 3, current ILD 306 flowing through the VCSEL diode 302 between the common electrical supply contact 305a (shared with the RCPD 312) and the electrical supply contact 305b of the VCSEL diode 302 creates a forward bias that generates the primary emission 340 directed towards a target object 350 through the substrate 308 and the on-chip lens 330. At the same time, current IPD 316 flowing through the RCPD 312 between the common electrical supply contact 305a (shared with the VCSEL diode 302) and the electrical supply contact 315a of the RCPD 312 creates a reverse bias through the RCPD 312. One or more controllers, such as the processor 1204 described with respect to FIG. 12 below, may be communicably connected to the optoelectronic sensing device 300 to enable configurations for forward-biasing the VCSEL diode 302 and the RCPD 312.

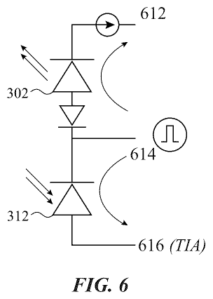

When the VCSEL diode 302 is forward-biased, the laser light of the primary emission 340 undergoes self-mixing interference in the laser cavity of the active region 307 upon reception of reflections or backscatters thereof. The RCPD 312 receives the self-mixed primary emission 340, and detects, when reverse-biased, an altered electrical property of the primary emission 340. In some embodiments, one or more controllers may be configured to switch a bias polarity of the RCPD 312 to capture multiple detections of the self-mixing interference in the time domain for a time-multiplexed sample read-out, as described with respect to FIG. 6.

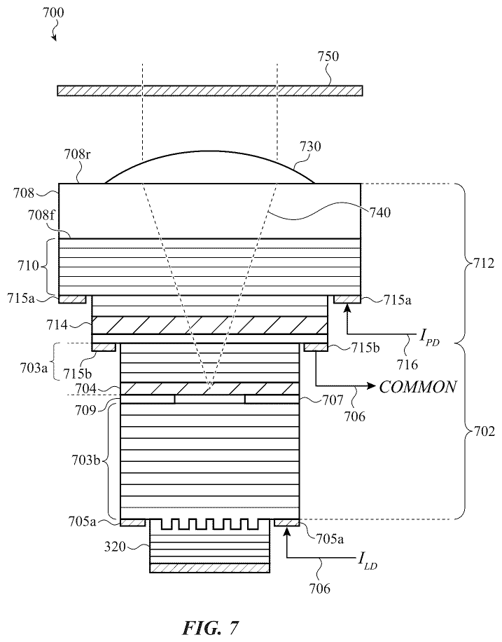

FIG. 4 shows a cross-sectional view of a grating structure 320 configured to be disposed on a set of stacked semiconductor layers such as, but not limited to, a substrate forming the example optoelectronic sensing device 300 of FIG. 3 or the example optoelectronic sensing device 700 of FIG. 7, described below. The grating structure 320 may be a diffraction grating structure having a grating period greater than a wavelength of the primary emission. Alternatively, the grating structure 320 may be a sub-wavelength grating structure having a grating period less than a wavelength of the primary emission. The grating structure 320 is an optional feature that can have different structural variations of the features described below, and may or may not be integrated in the optoelectronic sensing devices, depending on design requirements such as, but not limited to, stabilizing polarization of the emitted laser light.

The grating structure 320 is disposed on a top surface of the set of stacked semiconductor layers that can also include an electrical supply contact (e.g., electrical supply contact 315a in FIG. 3) forming a ring or a horseshoe around the grating structure 320. The grating structure 320 has a base layer 322 formed (using for example, atomic layer deposition) by a laterally-alternating arrangement of a high-index grating material 323 (e.g., amorphous silicon, GaAs) and a low-index grating material 324 (e.g., a dielectric material such as silicon oxide, aluminum oxide, silicon nitride). An optional dielectric stack 326 of alternating DBR layers and dielectric layers (e.g., silicon oxide, aluminum oxide, silicon nitride) may be disposed on the base layer 322. The set of DBR layers in the dielectric stack 326 aid in optical reflection of laser light from the VCSEL diode (e.g., VCSEL diode 302 of the optoelectronic sensing device 300). The grating structure 320 has an electrically conductive top layer 328 formed from a metal (e.g., gold, copper) disposed over the optional dielectric stack 326. The electrically conductive top layer 328 electrically connects the electrical supply contacts of the VCSEL diode and/or an RCPD, enhances optical reflection of emitted laser light, stabilizes any polarization of the emitted laser light, and also helps in bonding the grating structure 320 to other materials.

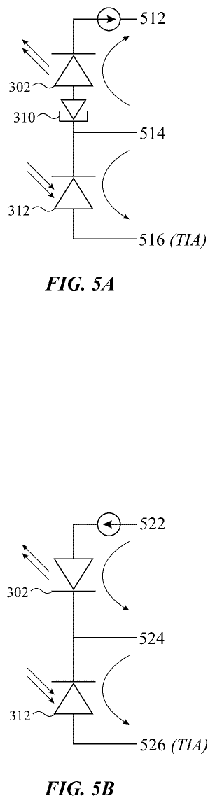

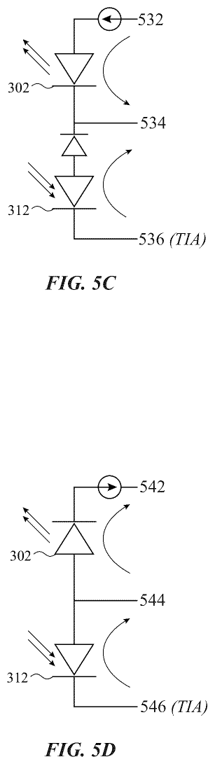

FIGS. 5A-5D show schematic representations of an operational circuit in the example optoelectronic sensing device 300 of FIG. 3. In FIG. 5A, the VCSEL diode 302 may be forward-biased between a first bias node 512 and a common node 514, while the RCPD 312 may be reverse-biased between the common node 514 and a second bias node 516. By way of example, the first bias node 512 may be driven to a positive voltage such as 0.2 V, the common node 514 may be driven to a positive voltage such as 3 V, and the second bias node 516 may have a positive voltage such as 1.5 V. The voltage of the second bias node 516 may depend on a transimpedance amplifier (TIA) or other readout circuitry connected thereto. In different embodiments, different voltage levels may be used for the first bias node 512, the common node 514, and the second bias node 516, and, in general, the voltage at the second bias node 516 is between the voltages at the first bias node 512 and the common node 514. Forward-biasing the VCSEL diode 302 may drive a cathode load current that causes the primary emission 340 to be emitted therefrom. Reverse-biasing the RCPD 312 may cause generation of a photocurrent when the RCPD 312 receives the primary emission 340 with an altered property due to self-mixing in the VCSEL diode 302. This photocurrent is detectable by the transimpedance amplifier (TIA) connected to the second bias node 516. In the configuration shown in FIG. 5A, the common node 514 has a n-contact and a tunnel junction 310 is present between the VCSEL diode 302 and the RCPD 312.

In FIG. 5B, the VCSEL diode 302 may be forward-biased between a first bias node 522 and a common node 524, while the RCPD 312 may be reverse-biased between the common node 524 and a second bias node 526. By way of example, the first bias node 522, the common node 524, and the second bias node 526 may be driven to progressively lower positive voltages such that, in general, the voltage at the common node 524 is between the voltages at the first bias node 522 and the second bias node 526. The voltage of the second bias node 526 may depend on a transimpedance amplifier (TIA) or other readout circuitry connected thereto. While in different embodiments, different sets of positive voltage levels may be used for the first bias node 522, the common node 524, and the second bias node 526, in the example shown in FIG. 5B, the first bias node 522 may be driven to 4.3 V, the common node 524 may be driven to 1.7 V, and the second bias node 526 may have 0.2 V. Forward-biasing the VCSEL diode 302 may drive an anode current that causes the primary emission 340 to be emitted therefrom. Reverse-biasing the RCPD 312 may cause generation of a photocurrent when the RCPD 312 receives the primary emission 340 with an altered property due to self-mixing in the VCSEL diode 302. This photocurrent is detectable by the TIA connected to the second bias node 526. In the configuration shown in FIG. 5A, the common node 524 has a n-contact.

In FIG. 5C, the VCSEL diode 302 may be forward-biased between a first bias node 532 and a common node 534, while the RCPD 312 may be reverse-biased between the common node 534 and a second bias node 536. By way of example, the first bias node 532 may be driven to a positive voltage such as 2.6 V, the common node 534 may be held at 0 V or ground (GND), and the second bias node 536 may have a positive voltage such as 1.5 V. The voltage of the second bias node 536 may depend on a transimpedance amplifier (TIA) or other readout circuitry connected thereto. In different embodiments, different voltage levels may be used for the first bias node 532, the common node 534, and the second bias node 536, and in general, the voltage at the second bias node 536 is between the voltages at the first bias node 532 and the common node 534. Forward-biasing the VCSEL diode 302 may drive an anode current that causes the primary emission 340 to be emitted therefrom. Reverse-biasing the RCPD 312 may cause generation of a photocurrent when the RCPD 312 receives the primary emission 340 with an altered property due to self-mixing in the VCSEL diode 302. This photocurrent is detectable by the TIA connected to the second bias node 536. In the configuration shown in FIG. 5C, the common node 534 has a n-contact and a native reverse junction is present between the VCSEL diode 302 and the RCPD 312.

In FIG. 5D, the VCSEL diode 302 may be forward-biased between a first bias node 542 and a common node 544, while the RCPD 312 may be reverse-biased between a second bias node 546 and the common node 544. By way of example, the first bias node 542, the common node 544, and the second bias node 546 may be driven to progressively higher positive voltages such that, in general, the voltage at the common node 544 is between the voltages at the first bias node 542 and the second bias node 546. The voltage of the second bias node 546 may depend on a transimpedance amplifier (TIA) or other readout circuitry connected thereto. While in different embodiments, different sets of positive voltage levels may be used for the first bias node 542, the common node 544, and the second bias node 546, in the example shown in FIG. 5D, the first bias node 542 may be held at 0 V or ground (GND), the common node 544 may be driven to a positive voltage of 2.6 V, and the second bias node 546 may have a positive voltage of 4.1 V. Forward-biasing the VCSEL diode 302 may drive a cathode load current that causes the primary emission 340 to be emitted therefrom. Reverse-biasing the RCPD 312 may cause generation of a photocurrent when the RCPD 312 receives the primary emission 340 with an altered property due to self-mixing in the VCSEL diode 302. This photocurrent is detectable by the TIA connected to the second bias node 546. In the configuration shown in FIG. 5D, the common node 544 has a p-contact.

FIG. 6 shows a schematic representations of an operational circuit in the example optoelectronic sensing device 300 of FIG. 3, where a bias polarity of the RCPD 312 is switched in the time domain. In FIG. 6, the VCSEL diode 302 may be forward-biased between a first bias node 612 and a common node 614, while the RCPD 312 may be reverse-biased or forward-biased between the common node 614 and a second bias node 616. In different embodiments, different voltage levels may be used for the first bias node 612, the common node 614, and the second bias node 616. Forward-biasing the VCSEL diode 302 may drive a cathode load current that causes the primary emission 340 to be emitted therefrom that is received by the RCPD 312 with an altered property due to self-mixing in the VCSEL diode 302, which then causes generation of a photocurrent. This photocurrent is detectable by a TIA connected to the second bias node 616. The bias polarity of the RCPD 312 may be switched in the time domain, which enables a time-multiplexed sample read-out of the photocurrent.

FIG. 7 shows a cross-sectional view of an example optoelectronic sensing device 700, having the second example structure 200 of a backside-emitting VCSEL diode integrated with an RCPD (shown in FIG. 2). In particular, a backside-emitting VCSEL diode 702 is integrated with an RCPD 712 that is disposed along a path of primary emission 740 of laser light generated from the VCSEL diode 702 under forward bias. The RCPD 712 receives an altered primary emission from the VCSEL diode 702 after the primary emission 740 undergoes self-mixing interference upon reception of reflections or backscatters therein.

The optoelectronic sensing device 700 is made by first depositing a set of mirror layers 710 on a front side 708f of a substrate 708. In some embodiments, the set of mirror layers 710 may be a DBR layer, such as those described above. An electrical supply contact 715a may be disposed on a top surface of the set of mirror layers 710, and may form a ring or horseshoe connection around the RCPD 712 deposited on the set of mirror layers 710. An on-chip lens 730 is disposed on a rear side 708r of the substrate 708, and is configured to collimate laser light emitted by the VCSEL diode 702 and to reflect a portion of the primary emission back toward the first active region in the VCSEL diode 702 and the RCPD 712.

The RCPD 712 is epitaxially deposited on the set of mirror layers 710. In some embodiments, the RCPD 712 may include an active region 714 and an electrical supply contact 715b disposed at a top surface thereof. The active region 714 may include one or more gain layers (e.g., InGaAs layer, AlGaAs layer) to improve efficiency of absorption of the altered primary emission 740 after it undergoes self-mixing interference in the active region 707 of the VCSEL diode 302. The electrical supply contact 715b forms a ring or horseshoe connection on the top side of the RCPD 312.

The VCSEL diode 702 is formed on the RCPD 712, such as by an epitaxial deposition technique. The VCSEL diode 702 may include an emission side (or “top side”) DBR layer 703a that functions as a first (or “emission side”) mirror of a laser structure. The emission side DBR layer 703a may include a set of pairs of alternating materials having different refractive indices. One or more of the materials in the emission side DBR layer 703a may be doped to be p-type and so form a part of the anode section of a p-n diode junction of the VCSEL diode 702. An exemplary pair of materials that may be used to form the emission side DBR layer 703a are AlGaAs and GaAs.

The VCSEL diode 702 may also include a base side DBR layer 703b that functions as a second (or “base side” or “bottom side”) mirror of a laser. The base side DBR layer 703b may also include a set of Bragg pairs of alternating materials having different refractive indices. One or more of the materials in the base side DBR layer 703b may be doped to be n-type and so form a part of the cathode section of a p-n diode structure. An exemplary pair of materials that may be used to form the base side DBR layer 703b are AlAs and GaAs.

In some embodiments, the DBR layers 703a and 703b may be formed by semiconductor epitaxy and either of the semiconductors GaAs, AlₓGa₁₋ₓAs for (0<x≤1), or from other semiconductor materials. In other embodiments, the DBR layers 703a and 703b may be formed from dielectric materials. Examples of such dielectrics include, but are not limited to, amorphous silicon (a-Si), silicon oxide (SiO₂), SiO₂/Nb₂O₅, and SiO₂/Ta₂O₅. In yet other embodiments, the DBR layers 703a and 703b may be formed as a hybrid of semiconductor materials and dielectric materials.

The VCSEL diode 702 may include an active region 707 that functions in part as the resonance cavity. In laser diodes, such as the VCSEL diode 702, the active region 707 may include one or more quantum wells. In some embodiments such as shown in FIG. 7, the active region 707 of the VCSEL diode 702 may be adjacent to an oxide layer 709 having an aperture through which the primary emission 740 escapes. In some embodiments such as shown in FIG. 7, the active region 707 further includes one or more gain stage layers 704 (e.g., InGaAs layer, AlGaAs layer) formed in the resonance cavity of the VCSEL diode 702 to improve efficiency of absorption of the primary emission 740.

The VCSEL diode 702 may be formed by epitaxial growth of the layers for each of the emission side DBR layers 703a and base side DBR layers 703b, the active region 707 and the oxide layer 709, and possibly other layers. These various layers may be formed by epitaxial growth on the RCPD 712. An electrical supply contact 705a may be formed on the base side layers of the VCSEL diode 702. A grating structure 320, as further described with respect to FIG. 4, may be disposed on the VCSEL diode 702.

One or more tunnel junctions (such as the tunnel junction 310 described with respect to FIG. 3) and additional gain layers (such as the additional gain layer 311 described with respect to FIG. 3) may be disposed between the active region 707 of the VCSEL diode 702 and the active region 714 of the RCPD 712. Depending on the polarities of the junctions, such tunnel junction(s) may help improve carrier injection/extraction from the VCSEL diode 702 to the RCPD 712 and reduce operating voltage of the optoelectronic sensing device 700.

As shown in FIG. 7, current ILD 706 flowing through the VCSEL diode 702 between the electrical supply contact 705a and the common electrical supply contact 715b (shared with the RCPD 712) of the VCSEL diode 702 creates a forward bias that generates the primary emission 740 directed towards a target object 750 through the substrate 708 and the on-chip lens 730. At the same time, current IPD 716 flowing through the RCPD 312 between the common electrical supply contact 715b (shared with the VCSEL diode 702) and the electrical supply contact 715a of the RCPD 712 creates a reverse bias through the RCPD 712. One or more controllers, such as the processor 1204 described with respect to FIG. 12 below, may be communicably connected to the optoelectronic sensing device 700 to enable configurations for forward-biasing the VCSEL diode 702 and the RCPD 712.

When the VCSEL diode 702 is forward-biased, the laser light of the primary emission 740 undergoes self-mixing interference in the laser cavity of the active region 707 upon reception of reflections or backscatters thereof. The RCPD 712 receives the self-mixed primary emission 740, and detects, when reverse-biased, an altered electrical property of the primary emission 740.

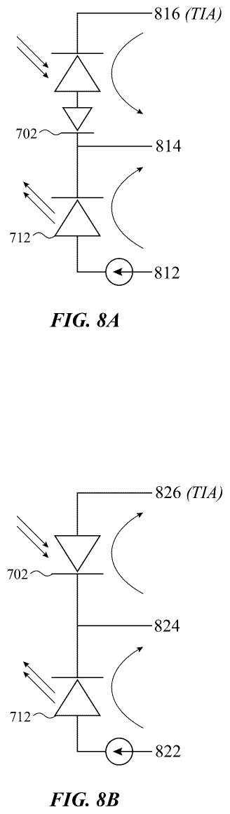

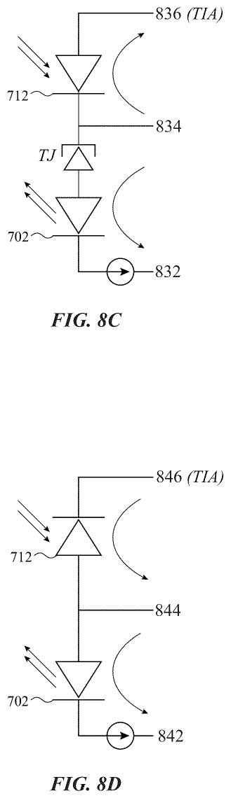

FIGS. 8A-8D show schematic representations of an operational circuit in the example optoelectronic sensing device 700 of FIG. 7. In FIG. 8A, the VCSEL diode 702 may be forward-biased between a first bias node 812 and a common node 814, and the RCPD 712 may be reverse-biased between the common node 814 and a second bias node 816. By way of example, the first bias node 812 may be driven to a positive voltage such as 2.6 V, the common node 814 may be held at 0 V or ground (GND), and the second bias node 816 may have a positive voltage such as 1.5 V. The voltage of the second bias node 816 may depend on a transimpedance amplifier (TIA) or other readout circuitry connected thereto. In different embodiments, different voltage levels may be used for the first bias node 812, the common node 814, and the second bias node 816. Forward-biasing the VCSEL diode 702 may provide an anode drive current that causes the primary emission 740 to be emitted therefrom. Reverse-biasing the RCPD 712 may cause generation of a photocurrent when the RCPD 712 receives the primary emission 740 with an altered property due to self-mixing in the VCSEL diode 702. This photocurrent is detectable by the TIA connected to the second bias node 816. In the configuration shown in FIG. 8A, the common node 814 has a n-contact and a native reverse junction is formed between the VCSEL diode 702 and the RCPD 712.

In FIG. 8B, the VCSEL diode 702 may be forward-biased between a first bias node 822 and a common node 824, while the RCPD 712 may be reverse-biased between the common node 824 and a second bias node 826. By way of example, the first bias node 822, the common node 824, and the second bias node 826 may be driven to progressively lower positive voltages. The voltage of the second bias node 826 may depend on a transimpedance amplifier (TIA) or other readout circuitry connected thereto. While in different embodiments, different sets of positive voltage levels may be used for the first bias node 822, the common node 824, and the second bias node 826, in the example shown in FIG. 8B, the first bias node 822 may be driven to 4.3 V, the common node 824 may be driven to 1.7 V, and the second bias node 826 may have 0.2 V. Forward-biasing the VCSEL diode 702 may drive an anode current that causes the primary emission 740 to be emitted therefrom. Reverse-biasing the RCPD 712 may cause generation of a photocurrent when the RCPD 712 receives the primary emission 740 with an altered property due to self-mixing in the VCSEL diode 702. This photocurrent is detectable by the TIA connected to the second bias node 826. In the configuration shown in FIG. 8B, the common node 824 has a n-contact.

In FIG. 8C, the VCSEL diode 702 may be forward-biased between a first bias node 832 and a common node 834, while the RCPD 712 may be reverse-biased between the common node 834 and a second bias node 836. By way of example, the first bias node 832 may be held at 0 V or ground (GND), the common node 834 may be driven to a positive voltage 2.8 V, and the second bias node 836 may have a positive voltage such as 1.3 V. The voltage of the second bias node 836 may depend on a transimpedance amplifier (TIA) or other readout circuitry connected thereto. In different embodiments, different voltage levels may be used for the first bias node 832, the common node 834, and the second bias node 836. Forward-biasing the VCSEL diode 702 may drive a cathode load current that causes the primary emission 740 to be emitted therefrom. Reverse-biasing the RCPD 712 may cause generation of a photocurrent when the RCPD 712 receives the primary emission 740 with an altered property due to self-mixing in the VCSEL diode 702. This photocurrent is detectable by the TIA connected to the second bias node 836. In the configuration shown in FIG. 8C, the common node 834 has a n-contact and a tunnel junction is present between the VCSEL diode 702 and the RCPD 712.

In FIG. 8D, the VCSEL diode 702 may be forward-biased between a first bias node 842 and a common node 844, while the RCPD 712 may be reverse-biased between a second bias node 846 and the common node 844. By way of example, the first bias node 842, the common node 844, and the second bias node 846 may be driven to progressively higher positive voltages. The voltage of the second bias node 846 may depend on a transimpedance amplifier (TIA) or other readout circuitry connected thereto. While in different embodiments, different sets of positive voltage levels may be used for the first bias node 842, the common node 844, and the second bias node 846, in the example shown in FIG. 8D, the first bias node 842 may be held at 0 V or ground (GND), the common node 844 may be driven to 2.6 V, and the second bias node 846 may have 4.1 V. Forward-biasing the VCSEL diode 702 may drive a cathode load current that causes the primary emission 740 to be emitted therefrom. Reverse-biasing the RCPD 712 may cause generation of a photocurrent when the RCPD 712 receives the primary emission 740 with an altered property due to self-mixing in the VCSEL diode 702. This photocurrent is detectable by the TIA connected to the second bias node 846. In the configuration shown in FIG. 8D, the common node 844 has a p-contact.

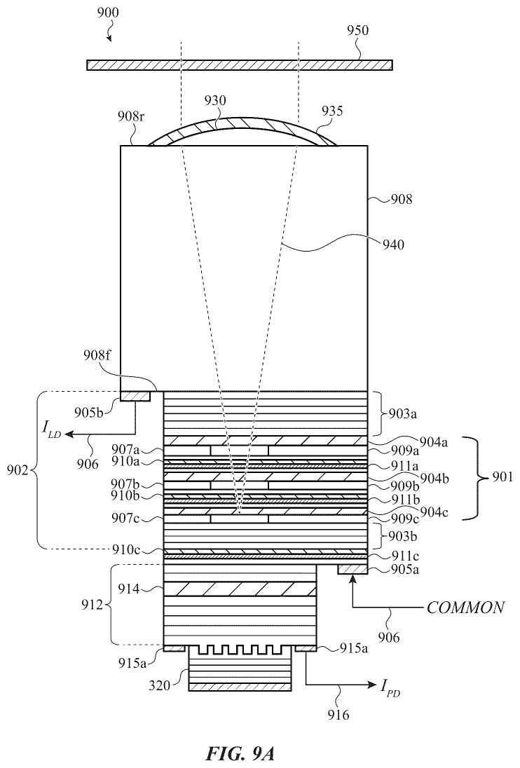

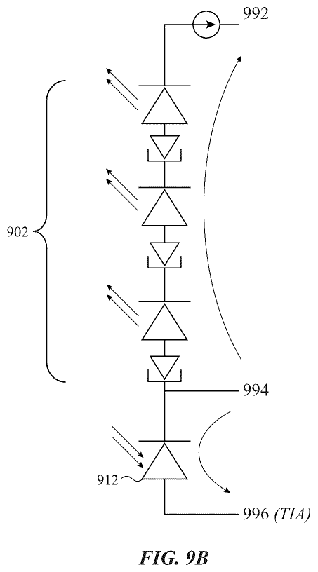

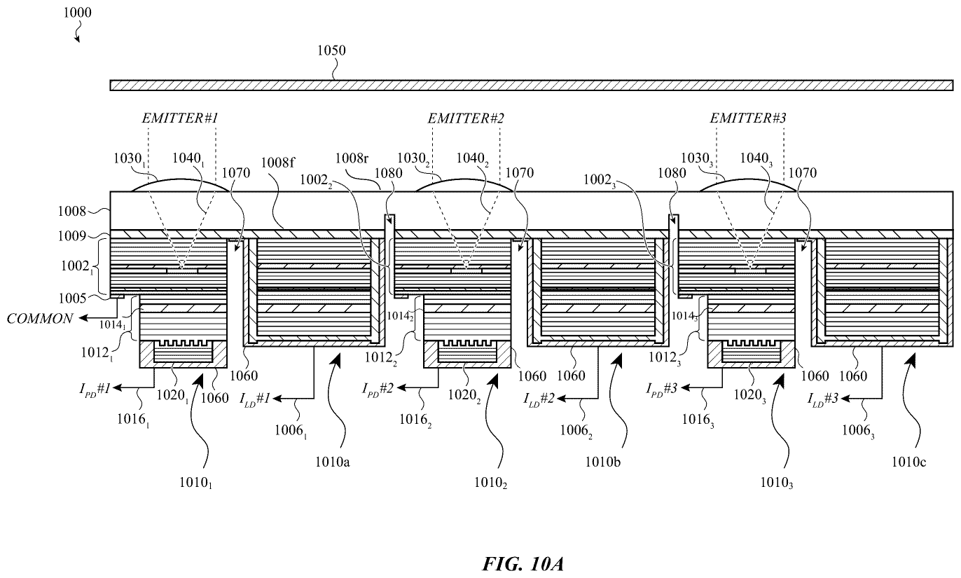

FIGS. 9A-9B show a cross-sectional view and a corresponding schematic representation of an operational circuit respectively, of a first example optoelectronic sensing device 900 having an extended resonance cavity in an emission side of a backside-emitting VCSEL diode having multi-junction structures (MJ-VCSEL) and integrated with an RCPD, as described below. The extended resonance cavity extends from the VCSEL diode to an on-chip lens (OCL) 930 formed on a rear side 908r of the substrate 908 and includes the substrate 908. In particular, FIG. 9A shows a backside-emitting MJ-VCSEL diode 902 integrated with an RCPD 912 that is disposed away from a path of primary emission 940 of laser light from the MJ-VCSEL diode 902 under forward bias. The RCPD 912 receives an altered primary emission 940 from the MJ-VCSEL diode 902 after the primary emission 940 undergoes self-mixing interference upon reception of reflections or backscatters therein.

The optoelectronic sensing device 900 is made by first forming a substrate 908 (e.g., a low-loss semiconductor or dielectric material) having an extended cavity, depositing a set of stacked semiconductor layers on a front side 908f of the substrate 908 to form the MJ-VCSEL diode 902 having a multi-junction structure 901, and then forming the RCPD 912 on the VCSEL diode 902. As discussed above, the extended resonance cavity significantly reduces laser linewidth and extends the laser coherence length needed for long-range sensing. The on-chip lens 930 is disposed on a rear side 908r of the substrate 908, and is configured to collimate laser light emitted by the VCSEL diode 902 and to collect returning laser light from target objects back toward the first active region in the VCSEL diode 902 and the RCPD 912. A reflective coating 935 made of a dielectric material may be disposed on the on-chip lens 930.

Similar to the embodiments described with respect to FIG. 3, the MJ-VCSEL diode 902 may include an emission side (or “top side”) DBR layer 903a including a set of pairs of alternating materials (e.g., AlGaAs, GaAs) having different refractive indices. The MJ-VCSEL diode 902 may also include a base side DBR layer 903b that also includes a set of Bragg pairs of alternating materials (e.g., AlAs, GaAs) having different refractive indices. One or more of the materials in the emission side DBR layer 903a and the base side DBR layer 903b may be doped to be p-type and n-type, respectively, and so form a part of the anode and cathode sections of a p-n diode structure, respectively.

Between the DBR layers 903a and 903b, MJ-VCSEL diode 902 may have multiple active regions 907a, 907b, 907c (e.g., multiple pairs of a barrier layer alternating with a quantum well layer) that generate laser light when stimulated by a forward bias voltage. The multiple active regions 907a, 907b, 907c may be interspersed with highly-doped tunnel junctions 910ₐ, 910_{b}, 910_{c} (similar to tunnel junction 310 described above with respect to FIG. 3) to form the vertically-stacked multi-junction structure 901 in the MJ-VCSEL diode 902. One or more gain layers 911a, 911b, 911c (similar to gain layer 311 described above with respect to FIG. 3) may be coupled to the tunnel junctions 910ₐ, 910_{b}, 910_{c} respectively in the multi-junction structure 901. While in the embodiment shown in FIG. 9A, there are three active regions 907a-907c interspersed with three tunnel junctions 910ₐ, 910_{b}, 910_{c} coupled to a respective one of three gain layers 911a, 911b, 911c, it should be noted that in other embodiments, an MJ-VCSEL diode 902 may have two or more than three of each type of layer that form a vertical stack between the DBR layers 903a and 903b.

Generally, in MJ-VCSEL diodes having a different number of active regions, there is a tunnel junction between each successive pair of active regions. As shown in FIG. 9A, in the MJ-VCSEL diode 902, there is a first tunnel junction 910ₐ between the active regions 907a and 907b, and a second tunnel junction 910_{b} between active regions 907b and 907c. Optionally, the MJ-VCSEL diode 902 may also include one or more tunnel junctions at locations other than between a successive pair of the active regions 907a-907c, such as the tunnel junction 910_{c} between the active region 907c and the RCPD 912. The tunnel junctions 910ₐ-910_{c} of the MJ-VCSEL diode 902 may be either homogenous or heterogenous. Semiconductor materials that may be used for the tunnel junction's layers include GaAs, AlₓGa₁₋ₓAs, InₓGa₁₋ₓAs, InₓGa₁₋ₓP, GaAs₁₋ₓNₓ, InₓGa₁₋ₓAs_{y}P_{1-y} for (0<x≤1, 0<y<1), and others as known to one skilled in the art. Depending on the polarities of the junctions, the tunnel junctions 910ₐ-910_{c} help improve carrier injection/extraction from the MJ-VCSEL diode 902 to the RCPD 912 and reduce operating voltage of the optoelectronic sensing device 900.

The active regions 907a-c each contain multiple barrier layers and quantum well layers. The materials that may be used for the barrier layers of the active regions 907a-c include AlₓGa₁₋ₓAs (0<x≤1), GaAs₁₋ₓPₓ (0<x≤1), and others known to one skilled in the art. The materials that may be used for the quantum wells of the active regions 907a-c include: InₓGa₁₋ₓAs (0<x≤1), InₓGa₁₋ₓAs_{y}N_{1-y}, (0<x≤1, 0<y≤1), InₓGa₁₋ₓAs_{1-y-z}N_{y}Sb_{z} (0<x≤1, 0<y<1, 0<z<1, y+z<1), and others known to one skilled in the art.

The MJ-VCSEL diode 902 includes an emission side (or “top”) oxide layer 909a positioned adjacent to the topmost active region 907a or on a top surface of the MJ-VCSEL diode 902, as well as a base side (or “bottom”) oxide layer 909c positioned adjacent to the bottommost active region 907c or on a bottom surface of the MJ-VCSEL diode 902. The oxide layer 909c includes an aperture (or multiple apertures) through which the primary emission 940 escapes. The MJ-VCSEL diode 902 may also include additional oxide layer 909b adjacent to the active region 907b. The oxide layers 909a and 909b each include an aperture (or multiple apertures) to allow the primary emission 940 to pass between the active regions 907a-907c. Other embodiments of MJ-VCSEL diodes may have none, or more than one, oxide layer between successive active regions. The apertures in the oxide layers 909a-c may allow laser light generated in the active regions 907a-907c to pass into each other and reinforce the generation of the primary emission 940 of laser light emitted through the optoelectronic sensing device 900.

In some embodiments such as shown in FIG. 9A, each of the active regions 907a-907c further include a respective one or more gain stage layers 904 (e.g., InGaAs layer, AlGaAs layer) formed in the resonance cavity of the MJ-VCSEL diode 902 to improve efficiency of re-absorption of the primary emission 940 into the MJ-VCSEL diode 902.

The MJ-VCSEL diode 902 may be formed by epitaxial growth of the layers for each of the emission side DBR layer 903a, the multi-junction structure 901, and the base side DBR layer 903b, on the substrate 908. Subsequently, the RCPD 912 is also formed on the MJ-VCSEL diode 902. In some embodiments, the RCPD 912 may include an active region 914, which may include one or more gain layers (e.g., InGaAs layer, AlGaAs layer) to improve efficiency of absorption of the altered primary emission 940 after it undergoes self-mixing interference in the active regions 907a-907c of the VCSEL diode 902. A grating structure 320, as further described with respect to FIG. 4, may be vertically disposed on the set of stacked semiconductor layers forming the RCPD 912.

The MJ-VCSEL diode 902 may have a common electrical supply contact 905a (shared with the RCPD 912) disposed on or proximate to the base side DBR layer 903b, a first electrical supply contact 905b disposed on or proximate to the emission side DBR layer 903a, and a second electrical supply contact 915a disposed on the RCPD 912. The common electrical supply contact 905a, the first electrical supply contact 905b, and the second electrical supply contact 915a may form a ring or horseshoe connection around the base side DBR layer 903b, the emission side DBR layer 903a, and the RCPD 912, respectively.

A bias voltage may be applied to cause the laser diode current ILD 906 to flow through the MJ-VCSEL diode 902 between the common electrical supply contact 905a and the first electrical supply contact 905b to generate the primary emission 940. This directs the primary emission 940 towards a target object 950 through the substrate 908 and the on-chip lens 930. At the same time, current IPD 916 flowing through the RCPD 912 between the common electrical supply contact 905a and the second electrical supply contact 915a of the RCPD 912 creates a reverse bias through the RCPD 912. One or more controllers, such as the processor 1204 described with respect to FIG. 12 below, may be communicably connected to the optoelectronic sensing device 900 to enable configurations for forward-biasing the VCSEL diode 902 and reverse-biasing the RCPD 912.

When the VCSEL diode 902 is forward-biased, the laser light of the primary emission 940 undergoes self-mixing interference in the laser cavity of the active regions 907a-c upon reception of reflections or backscatters thereof. The RCPD 912 receives the self-mixed primary emission 940, and detects, when reverse-biased, an altered electrical property of the primary emission 940.

The MJ-VCSEL diode 902 may emit laser light with different properties than would be emitted by the single junction VCSEL (SJ-VCSEL) diode 302 (shown in FIG. 3) operating at a similar current level. The MJ-VCSEL diode 902 operates at increased voltage levels (compared to the SJ-VCSEL diode 302 operating at a similar current level) and may provide multiple factors of increase of gain of, for example, output power. Also, the center frequency of the emitted laser light may be increased, which may improve signal-to-noise ratio (SNR) due to reduced 1/f noise. Increased SNR and higher operating frequency may also allow for improved spatial resolution of targets by the optoelectronic sensing device 900 with the MJ-VCSEL diode 902, due to increased efficiency and tunable range for wavelength modulation of the emitted laser light by the MJ-VCSEL diode 902, which in turn enables better measurement of the electrical parameter related to the self-mixing interference of the emitted laser light. Thus, the multi-junction structure 901 improves performance of the optoelectronic sensing device 900 through faster signaling, wider sampling and reduced complexity.

In FIG. 9B, the VCSEL diode 902 may be forward-biased between a first bias node 992 and a common node 994, while the RCPD 912 may be reverse-biased between the common node 994 and a second bias node 996. By way of example, the first bias node 992 may be driven to a positive voltage such as 0.2 V, the common node 994 may be driven to a positive voltage such as 6 V, and the second bias node 996 may be driven to a positive voltage such as 4.5 V. In different embodiments, different voltage levels may be used for the first bias node 992, the common node 994, and the second bias node 996. Forward-biasing the VCSEL diode 902 may drive a cathode load current that causes the primary emissions 940 to be emitted from the multi-junction structure 901 having the active regions 907a-907c interspersed with tunnel junctions 910ₐ-910_{c}. Reverse-biasing the RCPD 912 may cause generation of a photocurrent when the RCPD 912 receives the primary emissions 940 with an altered property due to self-mixing in the VCSEL diode 902. This photocurrent is detectable by a TIA or another readout circuitry connected to the second bias node 996. As discussed above, the multi-junction structure 901 in FIG. 9A increases thermal resistance as well as tunability of wavelength modulation for better measurement of self-mixing interference.

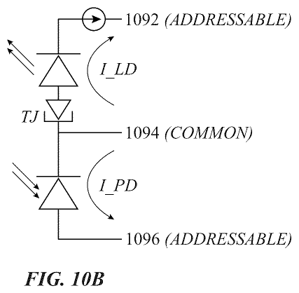

FIGS. 10A-10B show a cross-sectional view and a corresponding schematic representation of an operational circuit respectively, of a first example optoelectronic sensing device 1000 having multiple sets of a backside-emitting VCSEL diode (similar to the VCSEL diode 302 described with respect to FIG. 3) integrated with an RCPD (similar to the RCPD 312 described with respect to FIG. 3) that is disposed away from a primary emission path of the VCSEL diode. The optoelectronic sensing device 1000 has a first arrangement of electrical connections between the multiple sets, as described below.

As shown in FIG. 10A, the optoelectronic sensing device 1000 is made by forming an implantation layer 1009 on a front side 1008f of a substrate 1008, and then depositing (e.g., by an epitaxial deposition technique) a set of stacked semiconductor layers on the implantation layer 1009 to form a first set of mesas 1010₁, 1010₂, 1010₃ and a second set of mesas 1010ₐ, 1010_{b}, 1010_{c}. Although a set of three mesas are shown in the embodiment of FIG. 10A, each set of mesas in different embodiments may include more or fewer mesas forming a respective number of emitters. Each of the mesas 1010₁, 1010₂, 1010₃ include a respective backside-emitting VCSEL diode 1002₁, 1002₂, 1002₃ integrated with a respective RCPD 1012₁, 1012₂, 1012₃ disposed thereon. A respective grating structure 1020₁, 1020₂, 1020₃ is disposed on each of the respective RCPD 1012₁, 1012₂, 1012₃. Each of the mesas 1010₁, 1010₂, 1010₃ form a respective emitter #1, Emitter #2, Emitter #3, whereby a respective primary emission 1040₁, 1040₂, 1040₃ is emitted by the respective backside-emitting VCSEL diode 1002₁, 1002₂, 1002₃ through a respective on-chip lens 1030₁, 1030₂, 1030₃ disposed on a rear side 1008r of the substrate 1008.

Each of the respective VCSEL diodes 1002₁, 1002₂, 1002₃ may include a respective active region 1007₁, 1007₂, 1007₃ (similar to the active region 307 described with respect to FIG. 3) (not shown) that may include one or more quantum wells, and may be adjacent to a respective oxide layer (not shown) with an aperture through which the respective primary emission 1040₁, 1040₂, 1040₃ escapes. The respective active regions 1007₁, 1007₂, 1007₃ may also include respective gain stage layers 1004₁, 1004₂, 1004₃ (e.g., InGaAs layer, AlGaAs layer) (not shown) to improve efficiency of absorption of the respective primary emission 1040₁, 1040₂, 1040₃. The respective RCPD 1012₁, 1012₂, 1012₃ may include a respective active region 1014₁, 1014₂, 1014₃ that also includes one or more gain layers (e.g., InGaAs layer, AlGaAs layer) to improve efficiency of absorption of a respective altered primary emission 1040₁, 1040₂, 1040₃ after it undergoes self-mixing interference in the respective active region 1007₁, 1007₂, 1007₃ of the respective VCSEL diodes 1002₁, 1002₂, 1002₃. One or more tunnel junctions and gain layers may be disposed between the respective active region 1007₁, 1007₂, 1007₃ of the respective VCSEL diodes 1002₁, 1002₂, 1002₃ and the respective active region 1014₁, 1014₂, 1014₃ of the RCPD 1012₁, 1012₂, 1012₃.

When a respective VCSEL diode 1002₁, 1002₂, 1002₃ is forward-biased, the laser light of the respective primary emission 1040₁, 1040₂, 1040₃ undergoes self-mixing interference in the respective active region 1007₁, 1007₂, 1007₃ upon reception of reflections or backscatters thereof. A corresponding one of the RCPDs 1012₁, 1012₂, 1012₃ receives a respective self-mixed primary emission 1040₁, 1040₂, 1040₃, and detects, when reverse-biased, an altered electrical property of the respective self-mixed primary emission 1040₁, 1040₂, 1040₃.

In some embodiments, the first set of mesas 1010₁, 1010₂, 1010₃ and the second set of mesas 1010ₐ, 1010_{b}, 1010_{c} may be formed by epitaxially growing a common set of semiconductor layers, forming the trenches 1070, 1080 to define the respective mesas, and then electrically connecting a selected number of mesas to perform different functions or provide different routing structures. In the embodiment shown in FIG. 10A, a respective one of the second set of mesas 1010ₐ, 1010_{b}, 1010_{c} is adjacent to a respective one of the first set of mesas 1010₁, 1010₂, 1010₃ and are separated by a connecting trench 1070 (e.g., formed by etching through the set of stacked semiconductor layers). A first group of adjacent mesas 1010₁, 1010ₐ may be separated from a second group of adjacent mesas 1010₂, 10106 by an isolation trench 1080 (also formed by etching through the set of stacked semiconductor layers) that cuts through the implantation layer 1009 and provides electrical isolation between the respective active regions 1007₁, 1007₂, 1007₃ of the respective VCSEL diodes 1002₁, 1002₂, 1002₃. An electrically conductive layer 1060 (e.g., gold, copper) is disposed over the respective grating structure 1020₁, 1020₂, 1020₃ on each of the respective RCPDs 1012₁, 1012₂, 1012₃ and routed over each of the second set of mesas 1010ₐ, 1010_{b}, 1010_{c} to provide electrical connection across the set of mesas.

Each of the respective mesas 1010₁, 1010₂, 1010₃ includes a common electrical supply contact 1005 shared between the corresponding VCSEL diode 1002₁, 1002₂, 1002₃ and a respective RCPD 1012₁, 1012₂, 1012₃ disposed thereon. As shown in FIG. 10A, a bias voltage applied through the respective common electrical supply contact 1005 can create a forward bias (current ILD 1006₁, 1006₂, 1006₃) in each of the respective VCSEL diodes 1002₁, 1002₂, 1002₃ to generate the respective primary emission 1040₁, 1040₂, 1040₃ directed towards a target object 1050 through the substrate 1008 and the respective on-chip lens 1030₁, 1030₂, 1030₃. At the same time, a reverse bias (current IPD 1016₁, 1016₂, 1016₃) in each of the respective RCPDs 1012₁, 1012₂, 1012₃ helps in detecting an altered property of the respective primary emission 1040₁, 1040₂, 1040₃ due to self-mixing interference in the respective active regions 1007₁, 1007₂, 1007₃ of the respective VCSEL diode 1002₁, 1002₂, 1002₃. One or more controllers, such as the processor 1204 described with respect to FIG. 12 below, may be communicably connected to the optoelectronic sensing device 1000 to enable configurations for forward-biasing the respective VCSEL diode 1002₁, 1002₂, 1002₃ and reverse-biasing the respective RCPD 1012₁, 1012₂, 1012₃.

The particular arrangement of electrical connections in the optoelectronic sensing device 1000 with the electrically conductive layer 1160 enables individual addressability of each emitter formed by the respective one of the mesas 1010₁, 1010₂, 1010₃. As a result, any selection of one or more emitters Emitter #1, Emitter #2, Emitter #3 may be used as a sensor for detecting distance or motion of the target object 1050 using self-mixing interference captured by the respective backside-emitting VCSEL diode 1002₁, 1002₂, 1002₃ integrated with a respective RCPD 1012₁, 1012₂, 1012₃ disposed thereon.

As shown in FIG. 10B, each of the backside-emitting VCSEL diodes 1002₁, 1002₂, 1002₃ may be forward-biased between a first bias node 1092 and a common node 1094 (through the common electrical supply contact 1005), while the respective RCPD 1012₁, 1012₂, 1012₃ may be reverse-biased between the common node 1094 and a second bias node 1096. The first bias node 1092 and the common node 1094 may have different positive voltages such that the respective VCSEL diode 1002₁, 1002₂, 1002₃ is driven by a cathode load current that causes the respective primary emission 1040₁, 1040₂, 1040₃, to be emitted therefrom. The second bias node 1096 and the common node 1094 may also have different positive voltages, whereby the respective RCPD 1012₁, 1012₂, 1012₃ is reverse-biased such that a photocurrent is generated when the respective RCPD 1012₁, 1012₂, 1012₃ receives the respective primary emission 1040₁, 1040₂, 1040₃ with an altered property due to self-mixing in the VCSEL diodes 1002₁, 1002₂, 1002₃. This photocurrent is detectable by a TIA connected to the second bias node 1096. As discussed above, this arrangement enables addressability of individual emitters formed by the respective backside-emitting VCSEL diode 1002₁, 1002₂, 1002₃ integrated with a respective RCPD 1012₁, 1012₂, 1012₃ disposed thereon.

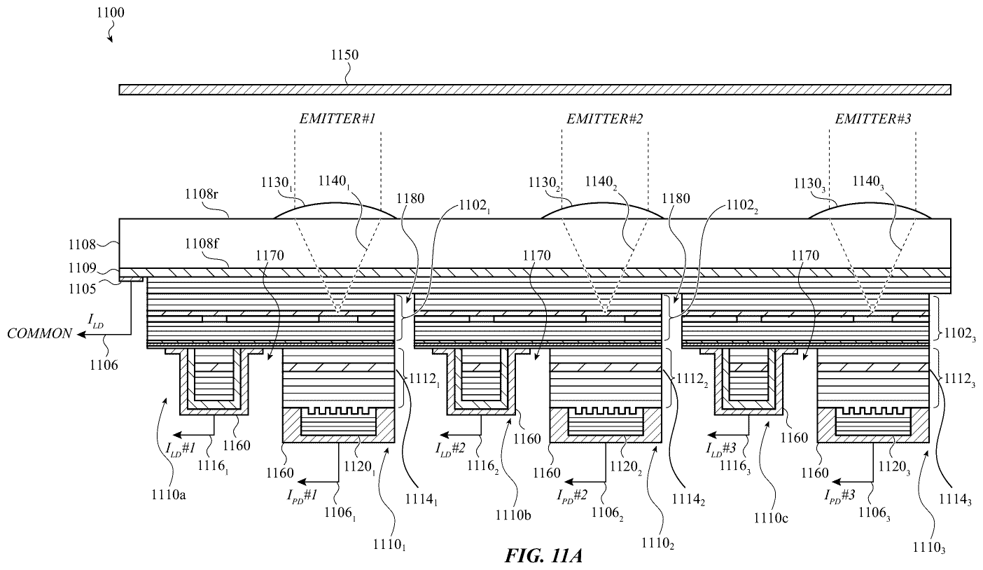

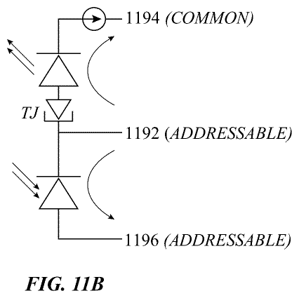

FIGS. 11A-11B show a cross-sectional view and a corresponding schematic representation of an operational circuit respectively, of a second example optoelectronic sensing device 1100 having multiple sets of a backside-emitting VCSEL diode (similar to the VCSEL diode 302 described with respect to FIG. 3) integrated with an RCPD (similar to the RCPD 312 described with respect to FIG. 3) that is disposed away from a primary emission path of the VCSEL diode. The optoelectronic sensing device 1100 has a first arrangement of electrical connections between the multiple sets, as described below.

As shown in FIG. 11A, the optoelectronic sensing device 1100 is made by forming an implantation layer 1109 on a front side 1108f of a substrate 1108, and then depositing (e.g., by an epitaxial deposition technique) a set of stacked semiconductor layers on the implantation layer 1109 to form a first set of mesas 1110₁, 1110₂, 1110₃ and a second set of mesas 1110ₐ, 1110_{b}, 1110_{c}. Although a set of three mesas are shown in the embodiment of FIG. 11A, each set of mesas in different embodiments may include more or fewer mesas forming a respective number of emitters. Each of the mesas 1110₁, 1110₂, 1110₃ include a respective backside-emitting VCSEL diode 1102₁, 1102₂, 1102₃ integrated with a respective RCPD 1112₁, 1112₂, 1112₃ disposed thereon. A respective grating structure 1120₁, 1120₂, 1120₃ is disposed on each of the respective RCPD 1112₁, 1112₂, 1112₃. Each of the mesas 1110₁, 1110₂, 1110₃ form a respective Emitter #1, Emitter #2, Emitter #3, whereby a respective primary emission 1140₁, 1140₂, 1140₃ is emitted by the respective backside-emitting VCSEL diode 1102₁, 1102₂, 1102₃ through a respective on-chip lens 1130₁, 1130₂, 1130₃ disposed on a rear side 1108r of the substrate 1108.

Each of the respective VCSEL diodes 1102₁, 1102₂, 1102₃ may include a respective active region 1107₁, 1107₂, 1107₃ (similar to the active region 307 described with respect to FIG. 3) (not shown) that may include one or more quantum wells, and may be adjacent to a respective oxide layer (not shown) with an aperture through which the respective primary emission 1140₁, 1140₂, 1140₃ escapes. The respective active region 1107₁, 1107₂, 1107₃ that may also include a respective gain stage layers 1104₁, 1104₂, 1104₃ (e.g., InGaAs layer, AlGaAs layer) (not shown) to improve efficiency of absorption of the respective primary emission 1140₁, 1140₂, 1140₃. The respective RCPD 1112₁, 1112₂, 1112₃ may include a respective active region 1114₁, 1114₂, 1114₃ that also includes one or more gain layers (e.g., InGaAs layer, AlGaAs layer) to improve efficiency of absorption of a respective altered primary emission 1140₁, 1140₂, 1140₃ after it undergoes self-mixing interference in the respective active region 1107₁, 1107₂, 1107₃ of the respective VCSEL diode 1102₁, 1102₂, 1102₃. One or more tunnel junctions and gain layers may be disposed between the respective active region 1107₁, 1107₂, 1107₃ of the respective VCSEL diode 1102₁, 1102₂, 1102₃ and the respective active region 1114₁, 1114₂, 1114₃ of the RCPD 1112₁, 1112₂, 1112₃.

When a respective VCSEL diode 1102₁, 1102₂, 1102₃ is forward-biased, the laser light of the respective primary emission 1140₁, 1140₂, 1140₃ undergoes self-mixing interference in the respective active region 1107₁, 1107₂, 1107₃ upon reception of reflections or backscatters thereof. A corresponding one of the RCPDs 1112₁, 1112₂, 1112₃ receives a respective self-mixed primary emission 1140₁, 1140₂, 1140₃, and detects, when reverse-biased, an altered electrical property of the respective self-mixed primary emission 1140₁, 1140₂, 1140₃.

In some embodiments, the first set of mesas 1110₁, 1110₂, 1110₃ and the second set of mesas 1110ₐ, 1110_{b}, 1110_{c} may be formed by epitaxially growing a common set of semiconductor layers, forming the trenches 1170, 1180 to define the respective mesas, and then electrically connecting a selected number of mesas to perform different functions or provide different routing structures. In the embodiment shown in FIG. 10A, a respective one of the second set of mesas 1110ₐ, 1110_{b}, 1110_{c} is adjacent to a respective one of the first set of mesas 1110₁, 1110₂, 1110₃ and are separated by a photodetector trench 1170 (e.g., formed by etching through the set of stacked semiconductor layers) that provides an electrical connection to a rear end of a respective one of the RCPDs 1112₁, 1112₂, 1112₃. Further, a first group of adjacent mesas 1110₁, 1110ₐ may be separated from a second group of adjacent mesas 1110₂, 1110_{b} by an oxidation trench 1180 (also formed by etching through the set of stacked semiconductor layers) that provides electrical isolation between the respective active regions 1107₁, 1107₂, 1107₃ of the respective VCSEL diodes 1102₁, 1102₂, 1102₃. An electrically conductive layer 1160 (e.g., gold, copper) is disposed over the respective grating structure 1120₁, 1120₂, 1120₃ on each of the respective RCPDs 1112₁, 1112₂, 1112₃, and over each of the second set of mesas 1110ₐ, 1110_{b}, 1110_{c}, to provide electrical connection across the set of mesas.

The optoelectronic sensing device 1100 includes a common electrical supply contact 1105 disposed on the implantation layer 1109 and shared by the respective backside-emitting VCSEL diodes 1102₁, 1102₂, 1102₃, and the respective RCPDs 1112₁, 1112₂, 1112₃, disposed thereon. As shown in FIG. 11A, a bias voltage applied through the common electrical supply contact 1105 can create a forward bias (current ILD 1106₁, 1106₂, 1106₃) in each of the respective VCSEL diodes 1102₁, 1102₂, 1102₃ to generate the respective primary emission 1140₁, 1140₂, 1140₃ directed towards a target object 1150 through the substrate 1108 and the respective on-chip lens 1130₁, 1130₂, 1130₃. At the same time, a reverse bias (current IPD 1116₁, 1116₂, 1116₃,) in each of the respective RCPDs 1112₁, 1112₂, 1112₃ helps in detecting an altered property of the respective primary emission 1140₁, 1140₂, 1140₃ due to self-mixing interference in the respective active regions 1107₁, 1107₂, 1107₃ of the respective VCSEL diode 1102₁, 1102₂, 1102₃. One or more controllers, such as the processor 1204 described with respect to FIG. 12 below, may be communicably connected to the optoelectronic sensing device 1100 to enable configurations for forward-biasing the respective VCSEL diode 1102₁, 1102₂, 1102₃ and reverse-biasing the respective RCPD 1112₁, 1112₂, 1112₃.

The particular arrangement of electrical connections in the optoelectronic sensing device 1100 with the electrically conductive layer 1160 enables individual addressability of each emitter formed by the respective one of the mesas 1110₁, 1110₂, 1110₃. As a result, any selection of one or more emitters Emitter #1, Emitter #2, Emitter #3, may be used as a sensor for detecting distance, or motion of the target object 1150 using self-mixing interference captured by the respective backside-emitting VCSEL diode 1102₁, 1102₂, 1102₃ integrated with a respective RCPD 1112₁, 1112₂, 1112₃ disposed thereon.

As shown in FIG. 11B, each of the backside-emitting VCSEL diodes 1102₁, 1102₂, 1102₃ may be forward-biased between a first bias node 1192 and a common node 1194 (through the common electrical supply contact 1105), while the respective RCPD 1112₁, 1112₂, 1112₃ may be reverse-biased between the first bias node 1192 and a second bias node 1196. The first bias node 1192 and the common node 1194 may have different positive voltages such that the respective VCSEL diode 1102₁, 1102₂, 1102₃ are driven by a cathode load current that causes the respective primary emission 1140₁, 1140₂, 1140₃ to be emitted therefrom. The first bias node 1192 and the second bias node 1196 may also have different positive voltages, whereby the respective RCPD 1112₁, 1112₂, 1112₃ is reverse-biased such that a photocurrent is generated when the respective RCPD 1112₁, 1112₂, 1112₃ receives the respective primary emission 1140₁, 1140₂, 1140₃ with an altered property due to self-mixing in the VCSEL diodes 1102₁, 1102₂, 1102₃. This photocurrent is detectable by a TIA connected to the second bias node 1196. As discussed above, this arrangement enables addressability of individual emitters formed by the respective backside-emitting VCSEL diode 1102₁, 1102₂, 1102₃ integrated with a respective RCPD 1112₁, 1112₂, 1112₃ disposed thereon.

FIGS. 12A-12B show a cross-sectional view and a corresponding schematic representation of an operational circuit respectively, of a second example optoelectronic sensing device 1200 having an extended resonance cavity in an emission side of a backside-emitting MJ-VCSEL diode and integrated with an RCPD, as described herein. The second example of an optoelectronic sensing device 1200 shown in and described with reference to FIGS. 12A-12B may have improved performance. In particular, the optoelectronic sensing device 1200 may have a relatively more stable polarization, and more stable in an optical mode than other optoelectronic sensing devices. In some cases, the optoelectronic sensing device 1200 may have a relatively higher signal strength for the RCPD output signal compared to other optoelectronic sensing devices.

The extended resonance cavity of the optoelectronic sensing device 1200 extends from the RCPD to an OCL 1230 formed on a rear side 1208r of the substrate 1208 and includes the substrate 1208. In particular, FIG. 12A shows a backside-emitting MJ-VCSEL diode 1202 integrated with an RCPD 1212 that is disposed in the path of primary emission 1240 of laser light from the MJ-VCSEL diode 1202 under forward bias. The RCPD 1212 receives an altered primary emission 1240 from the MJ-VCSEL diode 1202 after the primary emission 1240 undergoes self-mixing interference upon reception of reflections or backscatters therein.

The optoelectronic sensing device 1200 is made by first forming a substrate 1208 (e.g., a low-loss semiconductor or dielectric material) having an extended cavity, forming the RCPD 1212 on a front side 1208f of the substrate, and then depositing a set of stacked semiconductor layers on the RCPD 1212 to form the MJ-VCSEL diode 1202 having a multi-junction structure. As discussed above, the extended resonance cavity significantly reduces laser linewidth and extends the laser coherence length needed for long-range sensing. The OCL 1230 is disposed on a rear side 1208r of the substrate 1208, and is configured to collimate laser light emitted by the VCSEL diode 1202 and to collect returning laser light from target objects back toward the first active region in the VCSEL diode 1202 and the RCPD 1212. A reflective coating 1235 made of a dielectric material may be disposed on the OCL 1230. In other examples, a dielectric (multilayer) DBR may be disposed on the OCL 1230 to form a mirror for the extended resonance cavity.

In some examples, the OCL 1230 may be formed by etching the substrate 1208, resulting in a curved mirror. For example, the OCL 1230 may be formed using gray-scale lithography, or the OCL 1230 may be formed using reflowed photoresist. In other examples, the OCL 1230 may be formed from dielectric materials through a reflow process. In some examples the OCL 1230 may be a dielectric material or organic material.

In some examples, a reflective coating can be deposited on the OCL 1230 to form the mirror for the extended cavity of the optoelectronic sensing device 1200. In other examples, a dielectric (multilayer) DBR structure can be deposited on the OCL 1230 to form the mirror for the extended cavity of the optoelectronic sensing device 1200.

The optoelectronic sensing device 1200 may include an emission side (or “top side”) DBR layer 1203a including a set of pairs of alternating materials (e.g., AlGaAs, GaAs) having different refractive indices. Additionally, the MJ-VCSEL diode 1202 may also include a base side DBR layer 1203b that also includes a set of Bragg pairs of alternating materials (e.g., AlAs, GaAs) having different refractive indices. One or more of the materials in the emission side DBR layer 1203a and the base side DBR layer 1203b may be doped to be p-type and n-type, respectively, and so form a part of the anode and cathode sections of a p-n diode structure, respectively.

The MJ-VCSEL diode 1202 may have multiple active regions 1207a, 1207b, 1207c (e.g., multiple pairs of a barrier layer alternating with a quantum well layer) that generate laser light when stimulated by a forward bias voltage. The multiple active regions 1207a, 1207b, 1207c may be interspersed with highly-doped tunnel junctions 1210ₐ and 1210_{b} (similar to tunnel junction 310 described above with respect to FIG. 3) to form the vertically-stacked multi-junction structure in the MJ-VCSEL diode 1202. One or more gain layers 1211a, 1211b (similar to gain layer 311 described above with respect to FIG. 3) may be coupled to the tunnel junctions 1210ₐ, 1210_{b} respectively in the multi-junction structure in the MJ-VCSEL diode 1202. While in the embodiment shown in FIG. 12A, there are three active regions 1207a-1207c interspersed with two tunnel junctions 1210ₐ, 1210_{b} coupled to a respective one of two gain layers 1211a, 1211b, it should be noted that in other embodiments, an MJ-VCSEL diode 1202 may have two or more than three of each type of layer that form a vertical stack between the DBR layers 1203a and 1203b.

Generally, in MJ-VCSEL diodes having a different number of active regions, there is a tunnel junction between each successive pair of active regions. As shown in FIG. 12A, in the MJ-VCSEL diode 1202, there is a first tunnel junction 1210ₐ between the active regions 1207a and 1207b, and a second tunnel junction 1210_{b} between active regions 1207b and 1207c. Optionally, the MJ-VCSEL diode 1202 may also include one or more tunnel junctions (not shown) at locations other than between a successive pair of the active regions 1207a-1207c. The tunnel junctions 1210ₐ, 1210_{b} of the MJ-VCSEL diode 1202 may be either homogenous or heterogenous. Semiconductor materials that may be used for the tunnel junction's layers include GaAs, AlₓGa₁₋ₓAs, InₓGa₁₋ₓAs, InₓGa₁₋ₓP, GaAs₁₋ₓNₓ, InₓGa₁₋ₓAs_{y}P_{1-y} for (0<x≤1, 0<y<1), and others as known to one skilled in the art. Depending on the polarities of the junctions, the tunnel junctions 1210ₐ, 1210_{b} help improve carrier injection/extraction from the MJ-VCSEL diode 1202 to the RCPD 1212 and reduce operating voltage of the optoelectronic sensing device 1200.

The active regions 1207a-1207c each contain multiple barrier layers and quantum well layers. The materials that may be used for the barrier layers of the active regions 1207a-1207c include Al Ga₁₋ₓAs (0<x≤1), GaAs₁₋ₓPₓ (0<x≤1), and others known to one skilled in the art. The materials that may be used for the quantum wells of the active regions 1207a-1207c include: InₓGa₁₋ₓAs (0<x≤1), InₓGa₁₋ₓAs_{y}N_{1-y}, (0<x≤1, 0<y≤1), InₓGa₁₋ₓAs_{1-y-z}N_{y}Sb_{z} (0<x≤1, 0<y<1, 0<z<1, y+z<1), and others known to one skilled in the art.

The MJ-VCSEL diode 1202 includes an emission side (or “top”) oxide layer 1209a positioned adjacent to the topmost active region 1207a or on a top surface of the MJ-VCSEL diode 1202, as well as a base side (or “bottom”) oxide layer 1209c positioned adjacent to the bottommost active region 1207c or on a bottom surface of the MJ-VCSEL diode 1202. The oxide layer 1209c includes an aperture (or multiple apertures) through which the primary emission 1240 escapes. The MJ-VCSEL diode 1202 may also include additional oxide layer 1209b adjacent to the active region 1207b. The oxide layers 1209a and 1209b each include an aperture (or multiple apertures) to allow the primary emission 1240 to pass between the active regions 1207a-1207c. Other embodiments of MJ-VCSEL diodes may have none, or more than one, oxide layer between successive active regions. The apertures in the oxide layers 1209a-1209c may allow laser light generated in the active regions 1207a-1207c to pass into each other and reinforce the generation of the primary emission 1240 of laser light emitted through the optoelectronic sensing device 1200.

In some embodiments such as shown in FIG. 12A, each of the active regions 1207a, 1207b, 1207c further includes a respective one or more gain stage layers 1204a, 1204b, 1204c (e.g., InGaAs layer, AlGaAs layer) formed in the resonance cavity of the MJ-VCSEL diode 1202 to improve efficiency of re-absorption of the primary emission 1240 into the MJ-VCSEL diode 1202.

The emission side DBR layer 1203a and then the RCPD 1212 may be formed by epitaxial growth of the layers, on the substrate 1208, including the front side 1208f of the substrate 1208. Subsequently, the MJ-VCSEL diode 1202 may be formed by epitaxial growth on the RCPD 1212. The base side DBR layer 1203b may be formed by epitaxial growth on the MJ-VCSEL diode 1202.

In some embodiments, the RCPD 1212 may include an active region 1214, which may include one or more gain layers (e.g., InGaAs layer, AlGaAs layer) to improve efficiency of absorption of the altered primary emission 1240 after it undergoes self-mixing interference in the active regions 1207a-1207c of the VCSEL diode 902.

The MJ-VCSEL diode 1202 may have a common electrical supply contact 1205a (shared with the RCPD 1212) disposed on or proximate to the RCPD 1212, a first electrical supply contact 1205b disposed on or proximate to the emission side DBR layer 1203a, and a second electrical supply contact 1215a disposed on or proximate the base side DBR layer 1203b. The common electrical supply contact 1205a, the first electrical supply contact 1205b, and the second electrical supply contact 1215a may form a ring or horseshoe connection around the base side DBR layer 1203b, the emission side DBR layer 1203a, and the RCPD 1212, respectively.

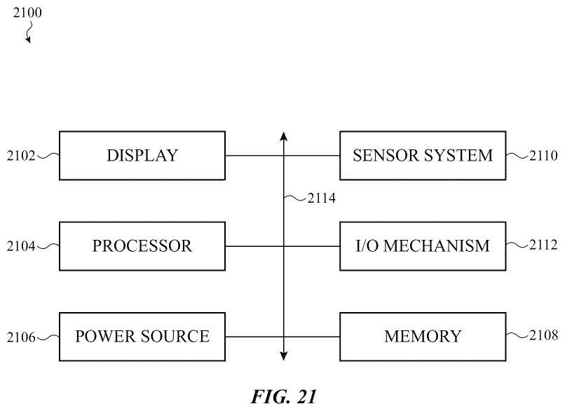

A bias voltage may be applied to cause the laser diode current ILD 1216, as a result of an applied laser diode voltage VLD, to flow through the MJ-VCSEL diode 1202 between the common electrical supply contact 1205a and the second electrical supply contact 1215a to generate the primary emission 1240. This generates the primary emission 1240 towards a target object (not shown) through the substrate 1208 and the OCL 1230. At the same time, current IPD 1206, as a result of an applied photodiode voltage VPD, flowing through the RCPD 1212 between the common electrical supply contact 1205a and the first electrical supply contact 1205b of the RCPD 1212 creates a reverse bias through the RCPD 1212. One or more controllers, such as the processor 2104 described with respect to FIG. 21 below, may be communicably connected to the optoelectronic sensing device 1200 to enable configurations for forward-biasing the VCSEL diode 1202 and reverse-biasing the RCPD 1212.

When the VCSEL diode 1202 is forward-biased, the laser light of the primary emission 1240 undergoes self-mixing interference in the laser cavity of the active regions 1207a-1207c upon reception of reflections or backscatters thereof. The RCPD 1212 receives the self-mixed primary emission 1240, and detects, when reverse-biased, an altered electrical property of the primary emission 1240.

The MJ-VCSEL diode 1202 may emit laser light with different properties than would be emitted by the single junction VCSEL (SJ-VCSEL) diode 302 (shown in FIG. 3) operating at a similar current level. The MJ-VCSEL diode 1202 operates at increased voltage levels (compared to the SJ-VCSEL diode 302 operating at a similar current level) and may provide multiple factors of increase of gain of, for example, output power. Also, the center frequency of the emitted laser light may be increased, which may improve SNR due to reduced 1/f noise. Increased SNR and higher operating frequency may also allow for improved spatial resolution of targets by the optoelectronic sensing device 1200 with the MJ-VCSEL diode 1202, due to increased efficiency and tunable range for wavelength modulation of the emitted laser light by the MJ-VCSEL diode 1202, which in turn enables better measurement of the electrical parameter related to the self-mixing interference of the emitted laser light. Thus, the multi-junction structure in the MJ-VCSEL diode 1202 improves performance of the optoelectronic sensing device 1200 through faster signaling, wider sampling and reduced complexity.

In FIG. 12B, the VCSEL diode 1202 may be forward-biased between a first bias node 1292 and a common node 1294, while the RCPD 1212 may be reverse-biased between the common node 1294 and a second bias node 1296. By way of example, the first bias node 1292 may be driven to a positive voltage, the common node 1294 may be driven to a lower positive voltage (e.g., ground), and the second bias node 1296 may also be driven to a positive voltage. In different embodiments, different voltage levels may be used for the first bias node 2392, the common node 1294, and the second bias node 1296. Forward-biasing the VCSEL diode 1202 may drive a cathode load current that causes the primary emission 1240 to be emitted from the multi-junction structure 1201 (depicted in FIG. 12A) having the active regions 1207a-1207c interspersed with tunnel junctions 1210ₐ, 1210_{b}. Reverse-biasing the RCPD 1212 may cause generation of a photocurrent when the RCPD 1212 receives the primary emission 1240 with an altered property due to self-mixing in the VCSEL diode 1202. This photocurrent is detectable by a TIA or another readout circuitry connected to the second bias node 1296. As discussed above, the multi-junction structure 1201 in FIG. 12A increases thermal resistance as well as tunability of wavelength modulation for better measurement of self-mixing interference.

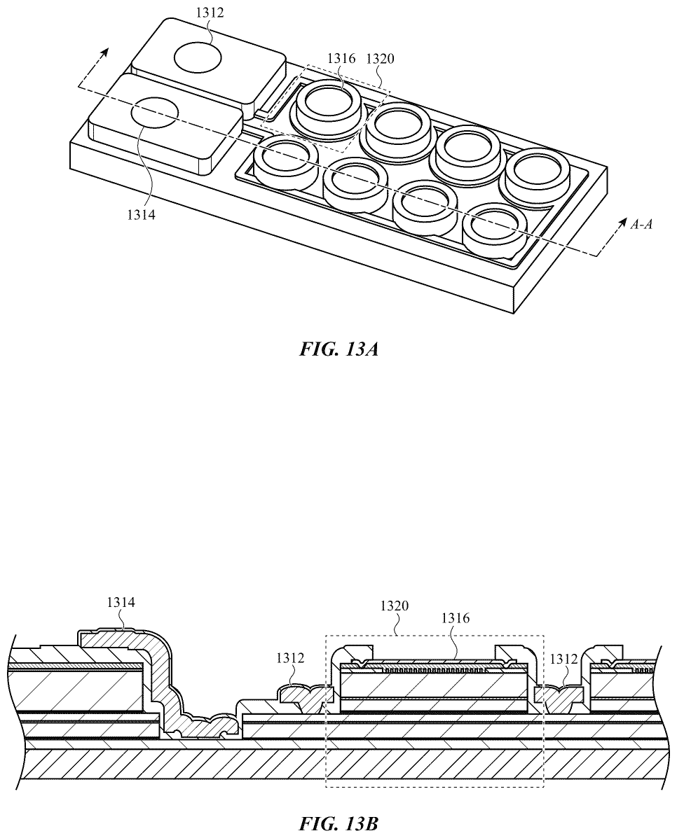

FIG. 13A shows a perspective view of a first example set of optoelectronic sensing devices, such as a set of the optoelectronic sensing devices shown and described with reference to FIGS. 9A-9B or 12A-12B. FIG. 13A generally depicts an example where a set of optoelectronic sensing devices 1320 (a bank of optoelectronic sensing devices) share a common photodiode bank contact and a common bank contact, and each optoelectronic sensing device has an individual (e.g., addressable) supply contact for the VCSEL diode.

The first example set of the optoelectronic sensing devices depicts eight instances of an optoelectronic sensing device 1320 arranged in two rows and four columns. Each optoelectronic sensing device 1320 may be an example of the optoelectronic sensing device 1200.

Each optoelectronic sensing device 1320 has an associated supply contact 1316. The supply contact 1316 is a conductive material (e.g., a p-contact) that is electronically coupled to a first bias node of the VCSEL of the optoelectronic sensing device 1320. In some examples, supply contact 1316 is an example of the first bias node 1292 and/or the second electrical supply contact 1215a.

The set of optoelectronic sensing devices share a common contact 1312 for the bank. The common contact 1312 is a conductive material that is electronically coupled to both a node of the VCSEL and a node of the RCPD, for example as more particularly described with reference to FIGS. 9A-9B or 12A-12B. In some examples, the common contact 1312 is an example of the common node 1294 and/or the common electrical supply contact 1205a.

The set of optoelectronic sensing devices share a common photodiode contact 1314 for the bank. The common photodiode contact 1314 is a conductive material (e.g., a n-contact) that is electronically coupled to a node of the RCPD, as more particularly described herein, for example with reference to FIGS. 9A-9B or 12A-12B. In some examples, the common photodiode contact 1314 is an example of the second bias node 1296 and/or the first electrical supply contact 1205b.

The common contact 1312, common photodiode contact 1314, and supply contacts 1316 are configured and oriented to be accessible for contact with conductors to provide electrical signals to and from the contacts of another device to which the optoelectronic sensing devices may be bonded. As further described herein, the first face of the set of optoelectronic sensing devices is the light-emitting face of the device, the first face being on an opposite side of the common contact 1312, common photodiode contact 1314, and supply contacts 1316. In some implementations, this arrangement of contacts may provide contacts to a two dimensional set of addressable dots, such as from a driver for the optoelectronic sensing devices. In some cases, wire bonding and pads to the outside of the array may thus be reduced or eliminated. Additionally, a quantity of emitters per array may be increased, and larger arrays of emitters may be utilized.

FIG. 13B shows a cross-sectional view through cross section A-A of FIG. 13A. The layers of optoelectronic sensing device 1320 are generally electrically coupled with the common contact 1312, common photodiode contact 1314, and supply contacts 1316 as shown. The common contact 1312 may form a ring around a central portion of the optoelectronic sensing device 1320.

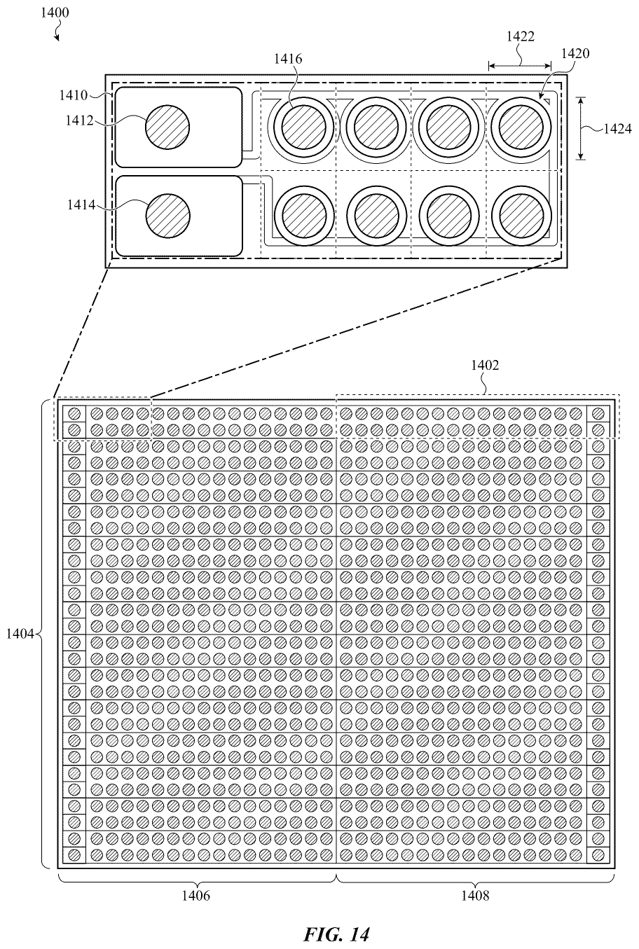

FIG. 14 shows a top view of an example sensing array 1400 including a set of optoelectronic sensing devices 1410. FIG. 14 generally depicts an example die architecture that includes an array of optoelectronic sensing devices, where each set (or bank) of optoelectronic sensing devices share a common contact and a common photodiode contact.

The set of optoelectronic sensing devices 1410 may be an example of the set of optoelectronic sensing devices shown and described with reference to FIGS. 13A-13B. The common contact 1412, common photodiode contact 1414, and supply contact 1416 associated with the optoelectronic sensing device 1420 of the set of optoelectronic sensing devices 1420 may be examples of the common contact 1312, common photodiode contact 1314, and supply contacts 1316 associated with the optoelectronic sensing device 1320. The optoelectronic sensing devices 1410 may be a portion of a larger bank 1402 of optoelectronic sensing devices.

In some examples, the sensing array 1400 may be a single die. The sensing array 1400 includes twenty-eight of the bank 1402 of thirty-two optoelectronic sensing devices arranged in a set of fourteen rows 1404 and two columns, including a first column 1406 and a second column 1408. Each bank 1402 (a bank of optoelectronic sensing devices) shares a common contact 1412 and a common photodiode contact 1414, and each optoelectronic sensing device 1420 has an individual (e.g., addressable) supply contact 1416 for the VCSEL diode.

As further described above, the contacts of the sensing array 1400 are on the face opposite the light-emitting face of the device, and are configured and oriented to be accessible for contact with another device, such as a driver. Each optoelectronic sensing device 1420 may have a width 1422 and a length 1424, comprising an area for the optoelectronic sensing device 1420. Because a bank 1402 of optoelectronic sensing devices 1420 may share a single one of the common contact 1412 and a single one of the common photodiode contact 1414, the area of the bank 1402 may be reduced relative to other optoelectronic sensing device architecture. For example, an architecture for a sensing array with an equivalent number of optoelectronic sensing devices where contacts are routed to the perimeter of the die may result in a larger area than the area of the sensing array 1400. Similarly, an architecture for a sensing array with an equivalent number of optoelectronic sensing devices where three contacts provided for each optoelectronic sensing device may also result in a larger area than the area of the sensing array 1400.

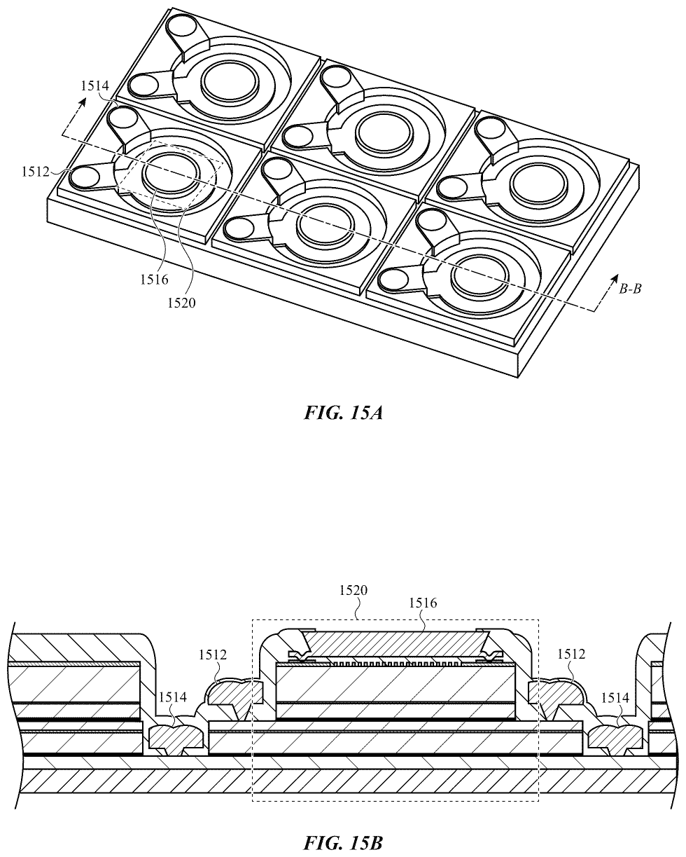

FIG. 15A shows a perspective view of a second example set of optoelectronic sensing devices, such as a set of the optoelectronic sensing devices shown and described with reference to FIGS. 9A-9B or 12A-12B. FIG. 15A generally depicts an example where each optoelectronic sensing device 1520 has an isolated photodiode. That is, each photodiode may be separately addressed and read out, for example as opposed to a bank of photodiodes being collectively read out as shown and described with reference to FIGS. 13A-14. Moreover, each optoelectronic sensing device 1520 has an individual (e.g., addressable) supply contact for the VCSEL diode.

The first example set of the optoelectronic sensing devices depicts six instances of an optoelectronic sensing device 1520 arranged in two rows and three columns. Each optoelectronic sensing device 1520 may be an example of the optoelectronic sensing device 1200. In some examples, each optoelectronic sensing device 1520 may be isolated from a neighboring optoelectronic sensing device 1520 by a trench structure (e.g., an insulated trench). Each optoelectronic sensing device 1520 may be an example of the optoelectronic sensing device 1200.

Each optoelectronic sensing device 1520 has an associated supply contact 1516. The supply contact 1516 is a conductive material (e.g., a p-contact) that is electronically coupled to a first bias node of the VCSEL of the optoelectronic sensing device 1520. In some examples, supply contact 1516 is an example of the first bias node 1292 and/or the second electrical supply contact 1215a.

Each optoelectronic sensing device 1520 also has an associated common contact 1512. The common contact 1512 is a conductive material that is electronically coupled to both a node of the VCSEL and a node of the RCPD, for example as more particularly described with reference to FIGS. 9A-9B or 12A-12B. In some examples, the common contact 1512 is an example of the common node 1294 and/or the common electrical supply contact 1205a.

Each optoelectronic sensing device 1520 also has an associated photodiode contact 1514. The photodiode contact 1514 is a conductive material (e.g., a n-contact) that is electronically coupled to a node of the RCPD, for example as more particularly described with reference to FIGS. 9A-9B or 12A-12B. In some examples, the photodiode contact 1514 is an example of the second bias node 1296 and/or the first electrical supply contact 1205b.

The common contact 1512, photodiode contact 1514, and supply contacts 1516 are configured and oriented to be accessible for contact with conductors to provide electrical signals to and from the contacts of another device to which the optoelectronic sensing devices may be bonded. As further described herein, the first face of the set of optoelectronic sensing devices is the light-emitting face of the device, the first face being on an opposite side of the common contact 1512, photodiode contact 1514, and supply contacts 1516. In some implementations, this arrangement of contacts may provide contacts to a two dimensional set of addressable dots, such as from a driver for the optoelectronic sensing devices. In some cases, wire bonding and pads to the outside of the array may thus be reduced or eliminated. Additionally, a quantity of emitters per array may be increased, and large arrays of emitters may be utilized.

FIG. 15B shows a cross-sectional view through cross section B-B of FIG. 15A. The layers of optoelectronic sensing device 1520 are generally electrically coupled with the common contact 1512, common photodiode contact 1514, and supply contacts 1516 as shown. The common contact 1512 may form a ring around a central portion of the optoelectronic sensing device 1520.

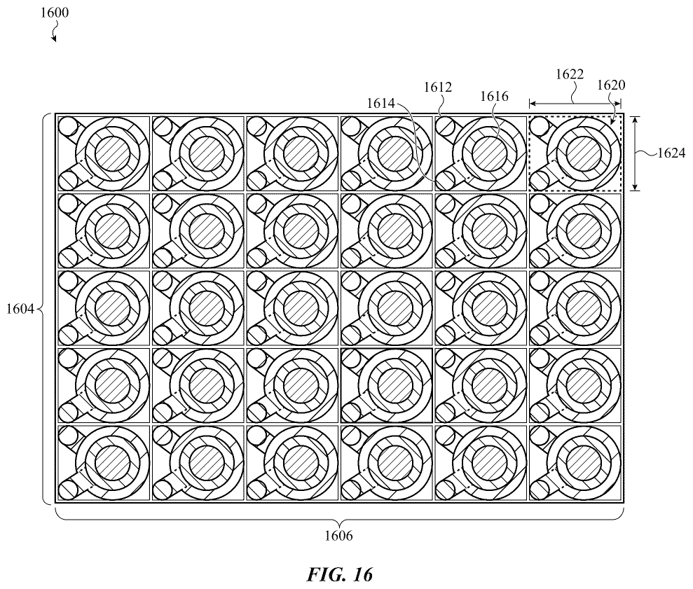

FIG. 16 shows a top view, of an example sensing array 1600 of optoelectronic sensing devices shown and described with reference to FIGS. 15A-15B. FIG. 15A generally depicts an example die architecture that includes an array of optoelectronic sensing devices, where three contacts of each optoelectronic sensing device are individually accessible.

The optoelectronic sensing device 1620 may be an example of the optoelectronic sensing devices 1520 shown and described with reference to FIGS. 15A-15B. The common contact 1612, common photodiode contact 1614, and supply contact 1616 associated with the optoelectronic sensing device 1620 may be examples of the common contact 1512, common photodiode contact 1514, and supply contacts 1516 associated with the optoelectronic sensing device 1520. The optoelectronic sensing device 1620 may be a portion of the larger sensing array 1600.

In some examples, the sensing array 1600 may be a single die. The sensing array 1600 includes thirty optoelectronic sensing devices arranged in a set of five rows 1604 and six columns 1606. Each optoelectronic sensing device has individual (e.g., addressable) contacts, including common contact 1612, common photodiode contact 1614, and supply contact 1616.

As further described above, the contacts of the sensing array 1600 are on the face opposite the light-emitting face of the device, and are configured and oriented to be accessible for contact with another device, such as a driver. Each optoelectronic sensing device 1620 may have a width 1622 and a length 1624, comprising an area for the optoelectronic sensing device 1620. Because the optoelectronic sensing devices 1620 may be accessed directly from a bonded device (e.g., a driver chip), the area of the sensing array 1600 may be reduced relative to other optoelectronic sensing device architectures. For example, an architecture for a sensing array with an equivalent number of optoelectronic sensing devices where contacts are routed to the perimeter of the die may result in a larger area than the area of the sensing array 1600.

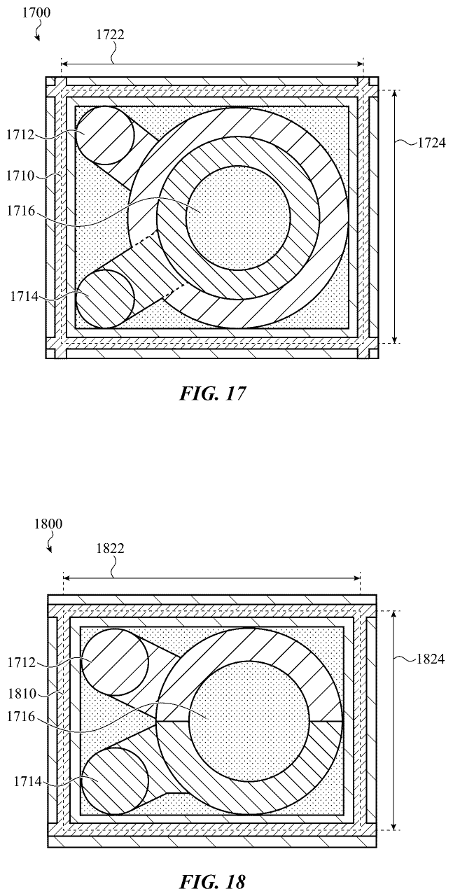

FIG. 17 shows a top view of a first example layout 1700 of an optoelectronic sensing device, for example an optoelectronic sensing device shown and described with reference to FIGS. 9A-9B or 12A-12B. The optoelectronic sensing device 1710 may be an example of one of the optoelectronic sensing devices shown and described with reference to FIGS. 9A-9B, 12A-12B, 15A-16. FIG. 17 generally depicts an example layout for an instance of an optoelectronic sensing device where a common contact 1712 and a photodiode contact 1714 each form a ring around a central portion of the optoelectronic sensing device 1710. The optoelectronic sensing device 1710 may have an area defined by a width 1722 and length 1724.

The common contact 1712, photodiode contact 1714, and supply contact 1716 associated with the optoelectronic sensing device 1710 may be examples of a common contact, common photodiode contact, and supply contact associated with another optoelectronic sensing device described herein, for example the common contact 1512, common photodiode contact 1514, and supply contacts 1516 associated with the optoelectronic sensing device 1520. The optoelectronic sensing device 1520 may be formed as a part of a larger sensing array, for example the sensing array 1600.

The common contact 1712 may generally form a first ring around the supply contact 1716 for the optoelectronic sensing device 1710. A portion of the common contact 1712 may extend away from the supply contact 1716, and be exposed so that the common contact may contact a conductor to form an electrical connection (e.g., to a chip driver to be bonded to an array of optoelectronic sensing device 1710). The non-exposed portion of the common contact 1712 (e.g., including the ring portion nearest the supply contact 1716) may be covered with a dielectric to protect the contact and prevent shorting.

Similarly, the photodiode contact 1714 may generally form a second ring around the first ring of the common contact 1712 and the supply contact 1716 for the optoelectronic sensing device 1710. A portion of the photodiode contact 1714 may extend away from the supply contact 1716, and be exposed so that the common contact may contact a conductor to form an electrical connection. The non-exposed portion of the photodiode contact 1714 (e.g., including the ring portion nearest the first ring for the common contact 1712 and the supply contact 1716) may be covered with a dielectric to protect the contact and prevent shorting.

FIG. 18 shows a top view of a second example layout 1800 of an optoelectronic sensing device, such as an optoelectronic sensing device shown and described with reference to FIGS. 9A-9B or 12A-12B. FIG. 18 generally depicts an example layout for an instance of an optoelectronic sensing device where the common contact 1712 forms a first half of a ring around a central portion of the optoelectronic sensing device 1810, and the photodiode contact 1714 forms a second half of a ring around the central portion of the optoelectronic sensing device 1810. In some examples, the first half of the ring and the second half of the ring may be in a same plane. In other examples, at least a portion of the first half of the ring may be in a different plane than at least a portion of the second half of the ring.

The common contact 1712, photodiode contact 1714, and supply contact 1716 associated with the optoelectronic sensing device 1810 may be examples of a common contact, common photodiode contact, and supply contact associated with another optoelectronic sensing device described herein. The optoelectronic sensing device 1820 may be formed as a part of a larger sensing array.

The common contact 1712 may generally form a first half of a ring around the supply contact 1716 for the optoelectronic sensing device 1810. A portion of the common contact 1712 may extend away from the supply contact 1716, and be exposed so that the common contact may contact a conductor to form an electrical connection. The non-exposed portion of the common contact 1712 (e.g., including the first half of the ring portion nearest the supply contact 1716) may be covered with a dielectric to protect the contact and prevent shorting.

Similarly, the photodiode contact 1714 may generally form a second half of a ring around the supply contact 1716 for the optoelectronic sensing device 1810. A portion of the photodiode contact 1714 may extend away from the supply contact 1716, and be exposed so that the common contact may contact a conductor to form an electrical connection. The non-exposed portion of the photodiode contact 1714 (e.g., including the second half of the ring portion nearest the supply contact 1716) may be covered with a dielectric to protect the contact and prevent shorting.

The optoelectronic sensing device 1810 may have an area defined by a width 1822 and length 1824. One or both of the length 1822 or the width 1824 for the optoelectronic sensing device 1810 may be less than the length 1722 or the width 1724 for the optoelectronic sensing device 1710 for an otherwise similar or equivalent optoelectronic sensing device. Generally, a single, split ring structure as shown and described with reference to the optoelectronic sensing device 1810 may have a relatively smaller area (e.g., and a relatively higher density) than a two ring structure as shown and described with reference to the optoelectronic sensing device 1710.

Although the second example layout 1800 shows a first half of a ring for the common contact 1712 and a second half of the ring for the photodiode contact 1714, the ring may be split according to different proportions. For example, a contact area to the optoelectronic sensing device 1810 may be tuned by changing the relative contact area, for example via a greater or lesser amount than half of the ring to one or the other of the contacts, between the common contact 1712 and the photodiode contact 1714.

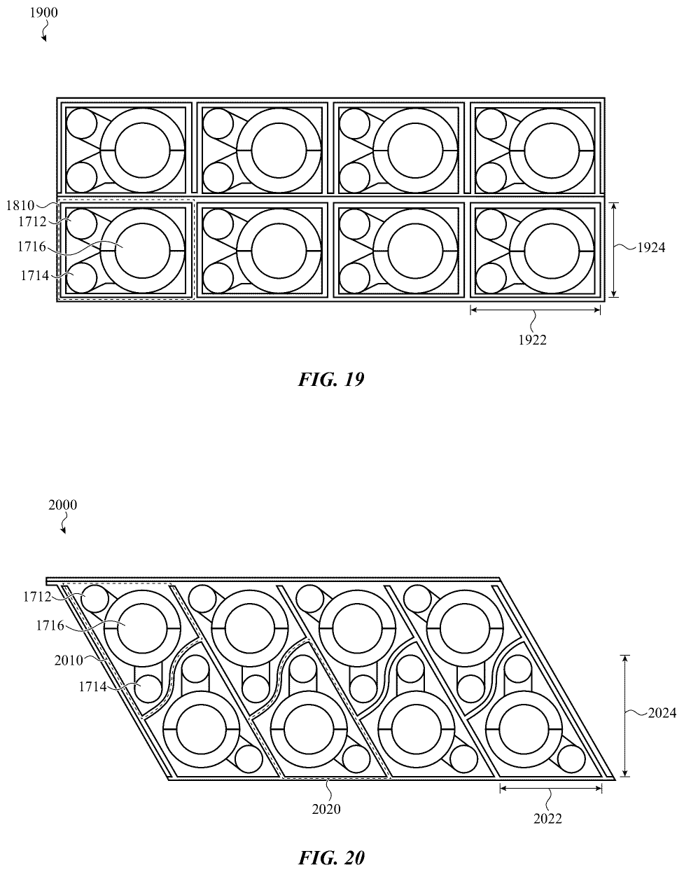

FIG. 19 shows a top view of a first array 1900 of the second example layout of an optoelectronic sensing device shown and described with reference to FIG. 18. FIG. 19 generally depicts a square or rectangular pattern (e.g., grid or array) of optoelectronic sensing devices 1810, where the unit area is according to a width 1922 and length 1924. The optoelectronic sensing device 1810 may be as shown and described with reference to the second example layout 1800.

FIG. 20 shows a top view of a second array 2000 of the second example layout of an optoelectronic sensing device shown and described with reference to FIG. 18. FIG. 20 generally depicts a hexagonal pattern (e.g., grid or array) of optoelectronic sensing devices, including optoelectronic sensing device 2010 and optoelectronic sensing device 2020, where the unit area is according to a width 2022 and length 2024.

The optoelectronic sensing device 2010 and optoelectronic sensing device 2020 may be similar to, but different from, the optoelectronic sensing device 1810 in the second example layout 1800. In particular, the optoelectronic sensing device 2010 may include the same central portion and split ring around the central portion, including the first half of the ring portion nearest the supply contact 1716 and the second half of the ring portion nearest the supply contact 1716. However, the portion of the common contact 1712 extending away from the supply contact 1716 and the portion of the photodiode contact 1714 extending away from the supply contact 1716 may be at different positions for the optoelectronic sensing device 2010. In particular, these portions may be generally configured to allow a hexagonal pattern for the second array 2000. In some examples, the layout of the optoelectronic sensing device 2010 is the same as the layout of the optoelectronic sensing device 2020, but rotated 180 degrees. In other examples, the locations of the common contact 1712 and the photodiode contact 1714 for the optoelectronic sensing device 2010 may be different (e.g., swapped) for the optoelectronic sensing device 2020.

In some examples, the unit area of the optoelectronic sensing device 2010 (according to the width 2022 and length 2024) may be less than the unit area of the optoelectronic sensing device 1810 (according to the width 1922 and length 1924). As such, in some examples of the second array 2000 of optoelectronic sensing devices may be smaller for a same quantity of devices (e.g., more dense, smaller pitch) than the first array 1900 of optoelectronic sensing devices.

FIG. 21 shows an example electrical block diagram of an electronic device 2100 having the optoelectronic sensor, such as the optoelectronic sensing device described with reference to FIG. 3. The electronic device 2100 may take forms such as a hand-held or portable device (e.g., a smartphone, tablet computer, or electronic watch), a navigation system of a vehicle, and so on. The electronic device 2100 may include an optional display 2102 (e.g., a light-emitting display), a processor 2104, a power source 2106, a memory 2108 or storage device, a sensor system 2110, and an optional input/output (I/O) mechanism 2112 (e.g., an input/output device and/or input/output port). The processor 2104 may control some or all of the operations of the electronic device 2100. The processor 2104 may communicate, either directly or indirectly, with substantially all of the components of the electronic device 2100. For example, a system bus or other communication mechanism 2114 may provide communication between the processor 2104, the power source 2106, the memory 2108, the sensor system 2110, and/or the input/output mechanism 2112.

The processor 2104 may be implemented as any electronic device capable of processing, receiving, or transmitting data or instructions. For example, the processor 2104 may be a microprocessor, a central processing unit (CPU), an application-specific integrated circuit (ASIC), a digital signal processor (DSP), or combinations of such devices. As described herein, the term “processor” is meant to encompass a single processor or processing unit, multiple processors, multiple processing units, or other suitably configured computing element or elements.

In some embodiments, the components of the electronic device 2100 may be controlled by multiple processors. For example, select components of the electronic device 2100 may be controlled by a first processor and other components of the electronic device 2100 may be controlled by a second processor, where the first and second processors may or may not be in communication with each other.

The power source 2106 may be implemented with any device capable of providing energy to the electronic device 2100. For example, the power source 2106 may include one or more disposable or rechargeable batteries. Additionally, or alternatively, the power source 2106 may include a power connector or power cord that connects the electronic device 2100 to another power source, such as a wall outlet.

The memory 2108 may store electronic data that may be used by the electronic device 2100. For example, the memory 2108 may store electronic data or content such as, for example, audio and video files, documents and applications, device settings and user preferences, timing signals, control signals, data structures or databases, image data, maps, or focus settings. The memory 2108 may be configured as any type of memory. By way of example only, the memory 2108 may be implemented as random access memory, read-only memory, Flash memory, removable memory, other types of storage elements, or combinations of such devices.

The electronic device 2100 may also include one or more optoelectronic sensors defining the sensor system 2110. The sensors may be positioned substantially anywhere on the electronic device 2100. The sensor(s) may be configured to sense substantially any type of characteristic, such as but not limited to, touch, force, pressure, electromagnetic radiation (e.g., light), heat, movement, relative motion, biometric data, distance, and so on. For example, the sensor system 2110 may include a touch sensor, a force sensor, a heat sensor, a position sensor, a light or optical sensor, an accelerometer, a pressure sensor (e.g., a pressure transducer), a gyroscope, a magnetometer, a health monitoring sensor, an image sensor, and so on. Additionally, the one or more sensors may utilize any suitable sensing technology, including, but not limited to, capacitive, ultrasonic, resistive, optical, ultrasound, piezoelectric, and thermal sensing technology.

The I/O mechanism 2112 may transmit and/or receive data from a user or another electronic device. An I/O device may include a display, a touch sensing input surface such as a track pad, one or more buttons (e.g., a graphical user interface “home” button, or one of the buttons described herein), one or more cameras (including one or more image sensors), one or more microphones or speakers, one or more ports such as a microphone port, and/or a keyboard. Additionally, or alternatively, an I/O device or port may transmit electronic signals via a communications network, such as a wireless and/or wired network connection. Examples of wireless and wired network connections include, but are not limited to, cellular, Wi-Fi, Bluetooth, IR, and Ethernet connections. The I/O mechanism 2112 may also provide feedback (e.g., a haptic output) to a user.

The foregoing description, for purposes of explanation, uses specific nomenclature to provide a thorough understanding of the described embodiments. However, it will be apparent to one skilled in the art, after reading this description, that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art, after reading this description, that many modifications and variations are possible in view of the above teachings.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. An optoelectronic sensing device comprising:
a vertical cavity surface emitting laser (VCSEL) diode at least partly defined by a first set of semiconductor layers disposed on a substrate, the first set of semiconductor layers including a first active region;
a resonance cavity photodetector (RCPD) vertically adjacent to the VCSEL diode and at least partly defined by a second set of semiconductor layers disposed on the substrate, the second set of semiconductor layers including a second active region; and
a tunnel junction disposed between the first active region of the first set of semiconductor layers and the second active region of the second set of semiconductor layers, wherein:
the VCSEL diode is configured to emit laser light towards the substrate, upon application of a first bias voltage, and undergo self-mixing interference upon reception of reflections or backscatters of the emitted laser light; and
the RCPD is configured to detect, upon application of a second bias voltage, the self-mixing interference during emission of the laser light by the VCSEL diode.

2. The optoelectronic sensing device of claim 1, wherein the VCSEL diode is disposed between the substrate and the RCPD.

3. The optoelectronic sensing device of claim 1, wherein the RCPD is disposed between the substrate and the VCSEL diode.

4. The optoelectronic sensing device of claim 3, further comprising:
a first electrical supply contact disposed on or proximate to one or more of the second set of semiconductor layers;
a second electrical supply contact disposed on or proximate to one or more of the first set of semiconductor layers; and
a common electrical supply contact disposed on or proximate to a layer between the first active region of the first set of semiconductor layers and the second active region of the second set of semiconductor layers.

5. The optoelectronic sensing device of claim 4, wherein:
the optoelectronic sensing device is a first optoelectronic sensing device of a bank of an array of a plurality of optoelectronic sensing devices, each optoelectronic sensing device of the plurality of optoelectronic sensing devices sharing a common photodiode bank contact coupled with the second electrical supply contact and sharing a common bank contact for the VCSEL diode coupled with the common electrical supply contact.

6. The optoelectronic sensing device of claim 4, wherein:
the optoelectronic sensing device is a first optoelectronic sensing device of an array of a plurality of optoelectronic sensing devices, each optoelectronic sensing device of the plurality of optoelectronic sensing devices having a photodiode contact coupled with the second electrical supply contact and a common contact for the VCSEL diode coupled with the common electrical supply contact.

7. The optoelectronic sensing device of claim 1, further comprising a controller configured to switch a bias polarity of the RCPD to capture multiple detections of the self-mixing interference in a time domain for a time-multiplexed sample read-out.

8. An optoelectronic sensing device comprising:
a substrate having a front side and a back side;
a set of stacked semiconductor layers disposed on the front side and defining:
a vertical cavity surface emitting laser (VCSEL) diode having a first active region within a resonance cavity thereof, the VCSEL diode configured to emit, upon application of a first bias voltage, a primary emission towards the substrate and through the back side; and
a resonance cavity photodetector (RCPD) having a second active region offset from the first active region; and
a grating structure disposed on the set of stacked semiconductor layers.

9. The optoelectronic sensing device of claim 8, wherein:
the VCSEL diode is forward-biased during the primary emission;
light emitted by the VCSEL diode during the primary emission undergoes self-mixing interference in the resonance cavity of the VCSEL diode upon reception of reflections or backscatters of the primary emission; and
the RCPD is configured to detect the self-mixing interference, upon application of a second bias voltage, during the primary emission by the VCSEL diode.

10. The optoelectronic sensing device of claim 8, wherein the grating structure is vertically disposed on the RCPD.

11. The optoelectronic sensing device of claim 8, wherein the VCSEL diode further includes a multi-junction stack within the resonance cavity of the VCSEL diode, the multi-junction stack including one or more gain stage layers interconnected with one or more tunnel junction layers stacked vertically.

12. The optoelectronic sensing device of claim 11, wherein the VCSEL diode further comprises one or more oxide layers formed on a top surface of the VCSEL diode, a bottom surface of the VCSEL diode, or within the multi-junction stack, each of the one or more oxide layers defining one or more oxide apertures.

13. The optoelectronic sensing device of claim 11, wherein the substrate defines at least part of an extended laser cavity separated from the multi-junction stack of the VCSEL diode by a set of distributed Bragg reflector (DBR) layers formed on the substrate.

14. The optoelectronic sensing device of claim 8, wherein the RCPD comprises one or more gain stage layers disposed within a resonance cavity of the RCPD, the one or more gain stage layers comprising indium gallium arsenide.

15. The optoelectronic sensing device of claim 8, further comprising:
an on-chip lens disposed on the back side of the substrate; and
a reflective coating disposed on the on-chip lens and configured to reflect a portion of the primary emission back toward the first active region.

16. The optoelectronic sensing device of claim 8, wherein the grating structure is filled with a dielectric material comprising one of: silicon oxide, aluminum oxide and silicon nitride.

17. An optoelectronic sensing device comprising:
a substrate having a front side and a back side;
a set of stacked semiconductor layers disposed on the front side and defining a set of mesas including:
a first set of one or more mesas, each mesa in the first set of one or more mesas including:
a vertical cavity surface emitting laser (VCSEL) diode having a first active region within a resonance cavity of the VCSEL diode and configured to emit, upon application of a first bias voltage, a primary emission towards the substrate and through the back side; and
a resonance cavity photodetector (RCPD) having a second active region offset from the first active region and configured to detect, upon application of a second bias voltage, a self-mixing interference of the primary emission in a laser cavity of the VCSEL diode upon reception of reflections or backscatters thereof;
a second set of one or more mesas; and
at least one electrical conductor electrically connected to an element of a first mesa in the first set of one or more mesas and routed over a portion of a second mesa in the second set of one or more mesas.

18. The optoelectronic sensing device of claim 17, wherein at least two adjacent mesas are operationally isolated by a trench etched through the set of stacked semiconductor layers, and an electrical conductor of the at least one electrical conductor is disposed in the trench.

19. The optoelectronic sensing device of claim 18, wherein the trench extends through the set of stacked semiconductor layers and into the substrate.

20. The optoelectronic sensing device of claim 17, wherein the at least one electrical conductor enables the RCPD in the first set of one or more mesas to be individually addressed.
